(19) United States
(12) Patent Application Publication
(10) Pub. No.: US 2025/0374609 A1
(43) Pub. Date: Dec. 4, 2025

(54) LAMINATE STRUCTURE AND THIN FILM TRANSISTOR

(71) Applicant: IDEMITSU KOSAN CO.,LTD., Tokyo (JP)

(72) Inventors: Yuki TSURUMA, Chiyoda-ku, Tokyo (JP); Emi KAWASHIMA, Chiyoda-ku, Tokyo (JP); Nobuhiro IWASE, Chiyoda-ku, Tokyo (JP); Koji YAMAGUCHI, Chiyoda-ku, Tokyo (JP); Hiroyuki MIWA, Chiyoda-ku, Tokyo (JP)

(73) Assignee: IDEMITSU KOSAN CO.,LTD., Tokyo (JP)

(21) Appl. No.: 18/870,318

(22) PCT Filed: May 25, 2023
(86) PCT No.: PCT/JP2023/019466

§ 371 Date: Nov. 27, 2024

(30) Foreign Application Priority Data
May 31, 2022 (JP) 2022-089264

(51) Int. Cl. H10D 30/67

(52) U.S. Cl. CPC H10D 30/6755; H10D 30/6731; H10D 30/6739

(57) ABSTRACT

Provided is a laminate structure, including: a crystalline oxide semiconductor film 11 containing In as a main component; and a first insulating film 12 laminated in contact with the crystalline oxide semiconductor film 11, wherein the crystalline oxide semiconductor film 11 has an average silicon concentration of 1.5 to 10 at %.

### CROSS-REFERENCE TO RELATED APPLICATIONS

The present application claims priority under 35 U.S.C. § 371 to International Patent Application No. PCT/JP2023/019466, filed May 25, 2023, which claims priority to and the benefit of Japanese Patent Application No. 2022-089264, filed on May 31, 2022. The contents of these applications are hereby incorporated by reference in their entireties.

### TECHNICAL FIELD

The present disclosure relates to a laminate structure and a thin film transistor.

### BACKGROUND ART

A thin film transistor (TFT) using an amorphous oxide semiconductor for a channel layer has been widely known (see Patent Document 1). However, the TFT has a low mobility, and hence there is a demand for improvement.

As a TFT that can obtain a high mobility characteristic as compared to the TFT using an amorphous oxide semiconductor for a channel layer, a TFT using a crystalline oxide semiconductor film as a channel layer has been known (see, for example, Patent Document 2).

### Related Art Documents Patent Document

[Patent Document 1] JP 5118810 B2
[Patent Document 2] WO 2013/035335 A1

### SUMMARY OF INVENTION

However, with the technology of Patent Document 2, a threshold voltage (Vth) may fluctuate at the time of use, for example, depending on the external environment such as high temperature and humidity, and problems in terms of reliability may occur.

Thus, in the related-art TFT using a crystalline oxide semiconductor film as a channel layer, there is room for improvement in terms of achievement of both the enhancement of the mobility and the reliability of the TFT.

An object of the present disclosure is to provide a laminate structure that exhibits a satisfactory mobility and obtains high reliability when applied to a TFT. In addition, another object of the present disclosure is to provide a thin film transistor having the laminate structure.

According to the present disclosure, the following laminate structure and the like are provided.

1. A laminate structure, including:
a crystalline oxide semiconductor film containing In as a main component; and
a first insulating film laminated in contact with the crystalline oxide semiconductor film,
wherein the crystalline oxide semiconductor film has an average silicon concentration of 1.5 to 10 at %.

2. The laminate structure according to Item 1, having a second insulating film laminated in contact with the surface of the crystalline oxide semiconductor film opposite to the surface in contact with the first insulating film.

3. The laminate structure according to Item 1 or 2, wherein the first insulating film is any one of an oxide film containing silicon (Si) as a main component, a nitride film containing silicon (Si) as a main component, and an oxynitride film containing silicon (Si) as a main component.

4. The laminate structure according to any one of Items 1 to 3, wherein the first insulating film is an oxide film containing silicon (Si) as a main component.

5. The laminate structure according to any one of Items 1 to 4, wherein the crystalline oxide semiconductor film further contains Ga.

6. The laminate structure according to any one of Items 1 to 5, wherein the crystalline oxide semiconductor film further contains one or more kinds of additive elements selected from B, Al, Si, Sc, Zn, Ge, Y, Zr, Sn, Sm, and Yb.

7. The laminate structure according to any one of Items 1 to 6, wherein an atomic ratio of In with respect to all metal elements contained in the crystalline oxide semiconductor film ([In]/([In]+[all metal elements except In])×100) is 62 at % or more.

8. The laminate structure according to any one of Items 5 to 7, wherein an atomic ratio of Ga with respect to all metal elements contained in the crystalline oxide semiconductor film ([Ga]/([Ga]+[all metal elements except Ga])×100) is 30 at % or less.

9. The laminate structure according to any one of Items 6 to 8, wherein an atomic ratio of a total amount of the additive elements with respect to all metal elements contained in the crystalline oxide semiconductor film ([total amount of additive elements]/([total amount of additive elements]+[all metal elements except additive elements])×100) is 10 at % or less.

10. The laminate structure according to any one of Items 1 to 9, wherein the crystalline oxide semiconductor film has a carrier concentration at room temperature of 1×10¹⁸ cm³ or less.

11. The laminate structure according to any one of Items 1 to 10, wherein the crystalline oxide semiconductor film contains a crystal grain having a bixbyite structure.

12. A thin film transistor, including the laminate structure of any one of Items 1 to 11,
wherein the thin film transistor includes:
a channel layer;
a source electrode and a drain electrode each connected to the channel layer, and
a gate electrode laminated on the channel layer through intermediation of a gate insulating film,
wherein the channel layer is the crystalline oxide semiconductor filmin the laminate structure, and
wherein the gate insulating film is the first insulating film in the laminate structure.

13. The thin film transistor according to Item 12, wherein the thin film transistor is a top-gate type transistor.

14. A semiconductor element, including the laminate structure of any one of Items 1 to 11.

15. A diode, a thin film transistor, a MOSFET, or a MESFET, including the semiconductor element of Item 14.

16. An electronic circuit, including the diode, the thin film transistor, the MOSFET, or the MESFET of Item 15.

17. An electric device, an electronic device, a vehicle, or a power engine, including the electronic circuit of Item 16.

According to the present disclosure, the laminate structure that exhibits a satisfactory mobility and obtains high reliability when applied to a TFT can be provided. In addition, the thin film transistor having the laminate structure can be provided.

### BRIEF DESCRIPTION OF DRAWINGS

FIG. 1 is a schematic sectional view of an example of a laminate structure of an aspect of the present disclosure.

FIG. 2 is another schematic sectional view of an example of a laminate structure of an aspect of the present disclosure.

FIG. 3 is a schematic sectional view of an example of a TFT of this aspect.

FIG. 4 is a schematic sectional view of another example of the TFT of this aspect.

FIG. 5 is a schematic sectional view of another example of the TFT of this aspect.

FIG. 6 is a schematic sectional view of a TFT produced in Example.

### DESCRIPTION OF EMBODIMENTS

The ordinal numbers “first,” “second,” and “third” as used herein are attached for avoiding confusion between constituents. Constituents without descriptions that specify the order are not limited to the numerical order of the ordinal numbers.

As used herein, the term “film” or “thin film” and the term “layer” are sometimes interchangeable with each other.

In a sintered body and an oxide thin film as used herein, the term “compound” and the term “crystal phase” are sometimes interchangeable with each other.

As used herein, the term “oxide sintered body” is sometimes simply referred to as “sintered body.”

As used herein, the term “sputtering target” is sometimes simply referred to as “target.”

As used herein, the term “electrically connected” encompasses connection through an “object of some electric action.” The “object of some electric action” is not particularly limited as long as the object allows communication of electric signals between connected components. Examples of the “object of some electric action” include an electrode, a line, a switching element (e.g., a transistor), a resistive element, an inductor, a capacitor, and other elements having various functions.

As used herein, the functions of the source and drain of a transistor may be interchanged when, for example, a transistor of different polarity is adopted or the direction of a current is changed during the operation of a circuit. Accordingly, the terms “source” and “drain” as used herein may be interchangeably used.

As used herein, the term “x to y” refers to a numerical range of “x or more and y or less.” An upper limit value and a lower limit value described regarding the numerical range may be arbitrarily combined.

In addition, the present disclosure also encompasses modes obtained by combining two or more individual modes of the present disclosure described below.

### 1. Laminate Structure

A laminate structure according to an aspect of the present disclosure includes a crystalline oxide semiconductor film containing In as a main component, and a first insulating film laminated in contact with the crystalline oxide semiconductor film.

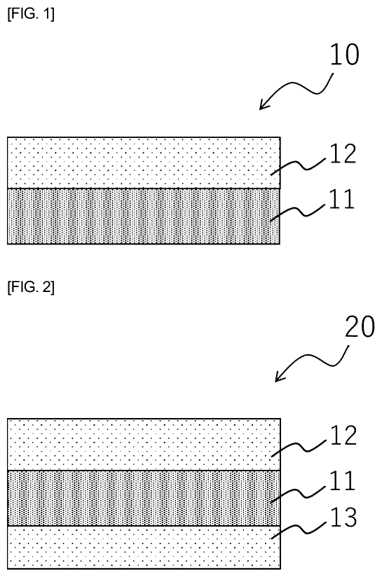

FIG. 1 is a schematic sectional view of an example of a laminate structure of an aspect of the present disclosure.

A laminate structure 10 includes a crystalline oxide semiconductor film 11, and a first insulating film 12 laminated in contact with the crystalline oxide semiconductor film 11.

### (Crystalline Oxide Semiconductor Film)

The crystalline oxide semiconductor film 11 in this aspect (hereinafter simply referred to as “crystalline oxide semiconductor film”) contains an In element as a main component. The In element being a main component means that the atomic ratio of In with respect to all metal elements in the crystalline oxide semiconductor film ([In]/([In]+[all metal elements except In])×100) (atomic %: at %) is 50 at % or more. The atomic ratio of In is preferably 62 at % or more, more preferably 70 at % or more, still more preferably 80 at % or more, yet still more preferably 84 at % or more, even yet still more preferably 85 at % or more. When the In element accounts for 50 at % or more of the total number of atoms of metal elements for forming the crystalline oxide semiconductor film, a sufficiently high mobility can be exhibited when the laminate structure according to this aspect is adopted in a TFT.

The crystalline oxide semiconductor film may be formed of a single crystalline oxide semiconductor or a polycrystalline oxide semiconductor. However, it is difficult to form a uniform single crystal on a substrate having a large area in many cases, and hence it is preferred that the crystalline oxide semiconductor film be formed of a polycrystalline oxide semiconductor.

The crystalline oxide semiconductor film has an average silicon concentration of 1.5 to 10 at %. The silicon concentration of the crystalline semiconductor film is a value obtained by the following formula (1). The expression “average silicon concentration” means that the silicon concentration may vary at each thickness portion of the crystalline oxide semiconductor film.

$$( Number of silicon ( Si ) atoms contained in crystalline oxide semiconductor film ) / ( Total number of atoms contained in crystalline oxide semiconductor film ) \times 100 \qquad ( 1 )$$

The measuring and calculating methods for the average silicon concentration will be explained in detail in Examples.

This increases the stability of the crystalline oxide semiconductor film, so that when a stacked structure having the crystalline oxide semiconductor film is applied to a TFT, the TFT has little fluctuation in the threshold voltage (Vth) and excellent reliability.

The average silicon concentration of the crystalline oxide semiconductor film may be 2.0 at % or higher, 2.4 at % or higher, 3.0 at % or higher, 4.0 at % or higher, or 4.9 at % or higher, or may be 9.5 at % or lower, 9.3 at % or lower, 8.7 at % or lower, 8.3 at % or lower, 8.0 at % or lower, 6.3 at % or lower, or 6.0 at % or lower.

The average silicon concentration of the crystalline oxide semiconductor film may be 2.0 to 9.3 at %, 2.4 to 8.7 at %, 3.0 to 8.0 at %, 4.0 to 6.3 at %, or 4.0 to 6.0 at %.

By setting the average silicon concentration of the crystalline oxide semiconductor film to the lower limit or higher, when a stacked structure having the crystalline oxide semiconductor film is applied to a TFT, the TFT has little fluctuation in the threshold voltage (Vth) and excellent reliability. By setting the average silicon concentration of the crystalline oxide semiconductor film to the upper limit or lower, when a stacked structure having the crystalline oxide semiconductor film is applied to a TFT, it is possible to suppress the phenomenon in which mobility decreases due to silicon acting as a scattering factor in the crystalline oxide semiconductor film, and good mobility is exhibited.

In one embodiment, the crystalline oxide semiconductor film may contain Ga in addition to In.

When the crystalline oxide semiconductor film contains Ga, the atomic ratio of Ga with respect to all metal elements in the crystalline oxide semiconductor film ([Ga]/([Ga]+[all metal elements except Ga])×100) (atomic %: at %) is preferably 30 at % or less, more preferably 20 at % or less, still more preferably 16 at % or less, yet still more preferably 15 at % or less.

When the Ga element accounts for 30 at % or less of the total number of atoms of metal elements for forming the crystalline oxide semiconductor film, a sufficiently high mobility can be exhibited when the laminate structure according to this embodiment is adopted in a TFT.

The crystalline oxide semiconductor film may contain, in addition to In, one or more elements selected from the group consisting of: H; B; C; N; O; F; Mg; Al; Si; O; S; Cl; Ar, Ca; Sc; Ti; V; Cr, Mn; Fe; Co; Ni; Cu; Zn; Ga; Ge; Y; Zr, Nb; Mo; Tc; Ru; Rh; Pd; Ag; Cd; Sn; Sb; Cs; Ba; Ln; Hf; Ta; W; Re; Os; Ir; Pt; Au; Pb; and Bi.

In one embodiment, the crystalline oxide semiconductor film may contain, in addition to In, one or more kinds of additive elements Z selected from B, Al, Si, Sc, Zn, Ge, Y, Zr, Sn, Sm, and Yb.

When the crystalline oxide semiconductor film contains the additive element Z, the atomic ratio of the total amount of the additive element Z with respect to all metal elements in the crystalline oxide semiconductor film ([total amount of additive element]/([total amount of additive element]+[all metal elements except additive element])×100) (atomic %: at %) is preferably 10 at % or less, more preferably 7.5 at % or less, still more preferably 5 at % or less.

When the total amount of the additive element Z is 10 at % or less of the total number of atoms of metal elements for forming the crystalline oxide semiconductor film, a sufficiently high mobility can be exhibited when the laminate structure according to this embodiment is adopted in a TFT.

In this embodiment, the crystalline oxide semiconductor film may consist essentially of elements selected from In, Mg, Al, Si, Zn, Ga, Mo, Sn, lanthanoid elements (Ln elements), and O. As used herein, the term “essentially” means that the crystalline oxide semiconductor film of the laminate structure according to this embodiment may contain any other component to the extent that the effects of the present disclosure attributed to the combination of In, Mg, Al, Si, Zn, Ga, Mo, Sn, Ln, and O described above are exhibited.

In the crystalline oxide semiconductor film according to a more preferred first mode of this embodiment, the metal elements consist of In and Ga, and the atomic ratios satisfy the following formula (11)

$$[ Ga ] / ( [ ln ] + [ Ga ] ) < 22 at \% \qquad ( 11 )$$

The crystalline oxide semiconductor film may contain inevitable impurities as the metal elements, and further F or H in addition to O. When the above-mentioned composition range is satisfied, the In ratio is increased, and crystallization to a bixbyite structure in which an In site is substituted by Ga can be achieved even by annealing at a low temperature such as 300° C. Further, when Ga having a strong bonding force with oxygen is added, oxygen deficiency after annealing is suppressed, and a film that is stable as a semiconductor can be formed.

The crystalline oxide semiconductor film according to a more preferred second mode of this embodiment consists of In, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as the metal elements, and when the metal element except In is represented by X, the atomic ratios satisfy the following formula (12).

$$[ X ] / ( [ ln ] + [ X ] ) < 15 at \% \qquad ( 12 )$$

The crystalline oxide semiconductor film may contain inevitable impurities as the metal elements, and further F or H in addition to O. When the above-mentioned composition range is satisfied, the In ratio is increased, and crystallization to a bixbyite structure in which an In site is substituted by X can be achieved even by annealing at a low temperature such as 300° C. Further, when the element X having a strong bonding force with oxygen is added, oxygen deficiency after annealing is suppressed, and a film that is stable as a semiconductor can be formed.

The crystalline oxide semiconductor film according to a more preferred third mode of this embodiment consists of In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as the metal elements, and when the metal element except In and Ga is defined as an additive element X, the atomic ratios satisfy the following formulae (13) and (14).

$$[ Ga ] / ( [ ln ] + [ Ga ] + [ X ] ) < 22.5 at \% \qquad ( 13 )$$

$$[ X ] / ( [ ln ] + [ Ga ] + [ X ] ) < 8.0 at \% \qquad ( 14 )$$

The crystalline oxide semiconductor film may contain inevitable impurities as the metal elements, and further F or H in addition to O.

When the above-mentioned composition range is satisfied, the In ratio is increased, and crystallization to a bixbyite structure in which an In site is substituted by Ga can be achieved even by annealing at a low temperature such as 300° C. In addition, when the additive element X having a strong bonding force with oxygen is added, oxygen deficiency after annealing is further suppressed, and a film that is stable as a semiconductor can be formed.

The crystalline oxide semiconductor film according to a more preferred fourth mode of this embodiment consists of In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb, and Lu as the metal elements, and when the metal element except In and Sn is defined as an element X, the atomic ratios satisfy the following formulae (15) and (16).

$$[ Sn ] / ( [ ln ] + [ Sn ] + [ X ] ) < 20 at \% \qquad ( 15 )$$

$$[ X ] / ( [ ln ] + [ Sn ] + [ X ] ) < 8. at \% \qquad ( 16 )$$

The crystalline oxide semiconductor film may contain inevitable impurities as the metal elements, and further F or H in addition to O.

When the composition range as described above is satisfied, the In ratio is increased, and crystallization to a bixbyite structure in which an In site is substituted by Sn can be achieved even by annealing at a low temperature such as 300° C. Sn has a large ion radius and a large orbital overlap with In, and hence a high mobility can be held. In addition, when the additive element X having a strong bonding force with oxygen is added, oxygen deficiency after annealing is further suppressed, and a film that is stable as a semiconductor can be formed.

The crystalline oxide semiconductor film according to a more preferred fifth mode of this embodiment consists of In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb, and Lu as the metal elements, and when the metal element except In and Zn is defined as an element X, the atomic ratios satisfy the following formulae (17) and (18).

$$[ Zn ] / ( [ ln ] + [ Zn ] + [ X ] ) < 12 at \% \qquad ( 17 )$$

$$[ X ] / ( [ ln ] + [ Zn ] + [ X ] ) < 8. at \% \qquad ( 18 )$$

The crystalline oxide semiconductor film may contain inevitable impurities as the metal elements, and further F or H in addition to O.

When the above-mentioned composition range is satisfied, the In ratio is increased, and crystallization to a bixbyite structure in which an In site is substituted by Zn can be achieved even by annealing at a low temperature such as 300° C. When Zn is added, the film immediately after film formation can be brought into an amorphous state, and the film can be processed without any residue at the time of semiconductor patterning with an acid during the production of a TFT. Further, when the additive element X having a strong bonding force with oxygen is added, oxygen deficiency after annealing is suppressed, and a film that is stable as a semiconductor can be formed.

The content (atomic ratio) of each metal element in the crystalline oxide semiconductor film may be determined by measuring the abundance of each element by inductively coupled plasma (ICP) measurement or X-ray fluorescence (XRF) measurement. An inductively coupled plasma optical emission spectrometer (ICP-OES manufactured by Agilent) may be used for the ICP measurement. A thin film X-ray fluorescence analyzer (AZX400 manufactured by Rigaku Corporation) may be used for the XRF measurement.

In one embodiment, the carrier concentration of the crystalline oxide semiconductor film is 1×10¹⁸ cm⁻³ or less, preferably 1×10¹⁷ cm⁻³ or less, more preferably 1×10¹⁶ cm³ or less. With this configuration, the Vth approaches 0 V in an Id-Vg curve when a Vd of 0.1 V is applied to drive a TFT, and satisfactory performance of normally-off characteristics is exhibited.

The carrier concentration is measured by the following method.

The crystalline oxide semiconductor film is cut out into a size of 1 cm square, and an electrode is connected to each of its four corners through use of In solder to provide an element for Hall effect measurement. Then, the carrier concentration is measured. The carrier concentration is determined by performing AC Hall effect measurement through use of Model ResiTest 8400 (manufactured by TOYO Corporation) at room temperature.

Measurement conditions are as described below. The value of the carrier concentration of electrons when an F value as measurement accuracy is 0.9 or more and the absolute value of a Hall voltage phase is from 170° to 180° is adopted.
Current value: 1×10⁻¹² A to 1×10⁻³ A
Magnetic field intensity: 0.36 T

In one embodiment, the thickness of the crystalline oxide semiconductor film is preferably smaller than 50 nm.

When the thickness of the crystalline oxide semiconductor film is smaller than 50 nm, a state in which silicon (Si) is appropriately diffused from the first insulating film side into the crystalline oxide semiconductor film during annealing of the first insulating film in the production process of the stacked structure described later is easily obtained, and a crystalline oxide semiconductor film having the above-mentioned average silicon concentration can be stably obtained.

The thickness of the crystalline oxide semiconductor film is preferably 42 nm or less, more preferably 32 nm or less, more preferably 30 nm or less, more preferably 20 nm or less, even more preferably 15 nm or less, even more preferably 11 nm or less, and particularly preferably 10 nm or less. On the other hand, the thickness of the crystalline oxide semiconductor film is, for example, 3 nm or more, may be 4 nm or more, may be 5 nm or more, or may be 8 nm or more. By making the thickness of the crystalline oxide semiconductor film to be 3 nm or more, it is possible to grow high-quality crystals without being affected by the underlayer during annealing crystallization (during formation of the crystalline oxide semiconductor film).

Herein, the thickness of a film is measured based on a cross-sectional TEM observation image (sometimes referred to as a “cross-sectional TEM image”).

The thickness of the crystalline oxide semiconductor film is not limited to the above range and may be, for example, 50 nm or more, 100 nm or more, or 200 nm or more, or 500 nm or less, 400 nm or less, or 300 nm or less.

In one embodiment, the crystalline oxide semiconductor film contains a crystal grain having a bixbyite structure in its electron beam diffraction. The crystal grain having a bixbyite structure has a cubic crystal shape with satisfactory symmetry, and hence a reduction in TFT characteristic (mobility) can be suppressed even across the crystal grain boundaries.

Whether or not the crystal grain in the crystalline oxide semiconductor film has a bixbyite structure is evaluated by observing the electron beam diffraction pattern of a sample obtained by observing the cross-sectional TEM image.

Specifically, an oxide thin film area observed in the cross-sectional TEM image is irradiated with an electron beam at an irradiation area of about 100 nmφ and an acceleration voltage of 200 kV with a selected area aperture through use of an electron microscope (“Model JEM-2800” manufactured by JEOL Ltd.), and the diffraction pattern is measured with a camera length set to 2 m.

Further, in order to identify the crystal structure, the electron beam diffraction pattern simulation of the bixbyite structure of In₂O₃ is performed with electron beam diffraction simulation software ReciPro (free software ver 4.641 (2019 Mar. 4)). In the simulation, for the crystal structure data of the bixbyite structure, 14388 of Inorganic Crystal Structure Database (ICSD: Japan Association for International Chemical Information) is used, and a space group of Ia-3, a lattice constant of a=10.17700 Å, and the atomic coordinates of an In site (0.250, 0.250, 0.250), an In site (0.466, 0.000, 0.250), and an O site (0.391, 0.156, 0.380) are used.

Further, the simulation is performed with a camera length of 2 m and 11 kinds of reciprocal lattice vectors (1 0 0), (1 1 1), (1 1 0), (2 1 1), (3 1 1), (2 2 1), (3 3 1), (2 1 0), (3 1 0), (3 2 1), and (2 3 0) as incident electron beam directions.

The results of the diffraction points of the electron beam diffraction pattern of the oxide thin film are compared to those of the resultant simulation pattern. When the result has matched any one of the 11 kinds of simulation patterns, it is judged that the oxide thin film contains a crystal grain having a bixbyite structure.

It is desired that the crystalline oxide semiconductor film contain a crystal grain having a Bixbyite structure. However, when an electron beam diffraction pattern can be recognized in an oxide thin film area observed with an electron microscope as described above, the oxide thin film may be regarded as a crystalline oxide semiconductor film.

### (First Insulating Film)

The first insulating film is not particularly limited, but typically contains a silicon (Si)-containing compound as a main component. “Containing a silicon (Si)-containing compound as a main component” means, for example, that the silicon (Si)-containing compound is 80 mass % or more, 90 mass % or more, 95 mass % or more, or substantially 100 mass % of the entire first insulating film. In addition, in the case of “substantially 100 mass %”, the first insulating film may contain unavoidable impurities.

Examples of silicon (Si)-containing compounds include SiO₂, SiNₓ, silicon oxynitride, and the like.

By laminating a first insulating film containing a silicon (Si)-containing compound as a main component in contact with the crystalline oxide semiconductor film, silicon (Si) is appropriately diffused from the first insulating film side into the crystalline oxide semiconductor film during annealing treatment of the first insulating film in a production process of a laminate structure described later, and a crystalline oxide semiconductor film having the above-mentioned average silicon concentration can be stably obtained.

The first insulating film may contain compounds other than the above-mentioned silicon (Si)-containing compound. Examples of the compounds other than the silicon (Si)-containing compound, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN may be mentioned. The oxidation numbers of the respective materials may be varied.

The content of the compound other than the silicon (Si)-containing compound contained in the first insulating film is typically 20 mass % or less based on the entire first insulating film.

The first insulating film is not necessarily limited to one containing a silicon (Si)-containing compound as a main component.

As long as the average silicon concentration of the above-mentioned crystalline oxide semiconductor film is within a predetermined range, the first insulating film may contain, for example, Al₂O₃ as a main component.

In one embodiment, the first insulating film is any one of an oxide film containing silicon (Si) as a main component, a nitride film containing silicon (Si) as a main component, and an oxynitride film containing silicon (Si) as a main component.

With this configuration, in the production process of the stacked structure described below, during the annealing treatment of the first insulating film, it is easier to obtain a state in which silicon (Si) is appropriately diffused into the crystalline oxide semiconductor film from the first insulating film side, and a crystalline oxide semiconductor film having the above-mentioned average silicon concentration can be stably obtained.

From the viewpoints of ease of availability and stability of the insulating film, the insulating film is more preferably an oxide film containing silicon (Si) as a main component.

The oxide film containing silicon (Si) as a main component means an oxide film in which the atomic ratio of silicon (Si) with respect to all cation atoms contained in the oxide film is 90 at % or more, the nitride film containing silicon (Si) as a main component means a nitride film in which the atomic ratio of silicon (Si) with respect to all cation atoms contained in the nitride film is 90 at % or more, and the oxynitride film containing silicon (Si) as a main component means an oxynitride film in which the atomic ratio of silicon (Si) with respect to all cation atoms contained in the oxynitride film is 90 at % or more.

The film thickness of the first insulating film is, for example, 10 nm or more, and may be 98 nm or more, 100 nm or more, 120 nm or more, or 300 nm or more.

By making the film thickness of the first insulating film 10 nm or more, it is easy to obtain a state in which silicon (Si) is moderately diffused into the crystalline oxide semiconductor film from the first insulating film side during annealing of the first insulating film in the manufacturing process of the stacked structure described below, and a crystalline oxide semiconductor film having the above-mentioned average silicon concentration is stably obtained.

The upper limit of the film thickness of the first insulating film is not particularly limited, but is, for example, 500 nm or less, may be 210 nm or less, 200 nm or less, or may be 150 nm or less.

By making the film thickness of the first insulating film 500 nm or less, a stable device shape is obtained when the laminate structure of this embodiment is applied to a TFT.

The first insulating film 12 may be a single-layer film or a laminated film. When the first insulating film 12 is a laminated film, the preferable thickness described for the first insulating film 12 is the thickness of the entire laminated film.

FIG. 2 is a schematic cross-sectional view of a laminate structure 20 according to another example of the present aspect. The lamintate structure 20 includes a crystalline oxide semiconductor film 11, a first insulating film 12 laminated in contact with the crystalline oxide semiconductor film 11, and a second insulating film 13 laminated in contact with the surface of the crystalline oxide semiconductor film 11 opposite to the contact surface with the first insulating film 12.

The laminate structure 20 shown in FIG. 2 is the same as the laminate structure 10 shown in FIG. 1 except that the second insulating film 13 is provided.

The second insulating film 13 is not particularly limited, but typically contains a silicon (Si)-containing compound as a main component. The preferred material composition of the second insulating film 13 is the same as the preferred material composition described for the first insulating film 12.

By laminating the second insulating film 13 containing a silicon (Si)-containing compound as a main component on the surface of the crystalline oxide semiconductor film 11 opposite to the contact surface with the first insulating film 12, it is possible to suppress silicon (Si) that has diffused from the first insulating film 12 side into the crystalline oxide semiconductor film 11 during annealing of the first insulating film 12 in a production process of a laminate structure described later from diffusing into a layer or member opposite to the contact surface with the first insulating film 12. Therefore, the crystalline oxide semiconductor film 11 having the above-mentioned average silicon concentration can be stably obtained.

The thickness of the second insulating film is not particularly limited, but from the viewpoint of shape stability of the device when applied to a TFT, it may be 100 nm or more, 150 nm or more, or 200 nm or more, and may be 500 nm or less, 450 nm or less, or 400 nm or less.

The second insulating film 13 may be a single-layer film or a laminated film. When it is a laminated film, the preferred thickness of the second insulating film 13 is the thickness of the entire laminated film.

### 2. Method of Producing Laminate Structure

The laminate structure of this aspect may be produced, for example, by forming an oxide thin film containing an oxide of In as a main component on a lower layer or the like for forming a TFT, such as a substrate, a buffer layer, or an insulating layer, and subjecting the oxide thin film to crystallization treatment to form a crystalline oxide semiconductor film (crystalline oxide semiconductor film formation step), and then forming a first insulating film in contact with the crystalline oxide semiconductor film as a Si supply process to the crystalline oxide semiconductor film (first insulating film formation step), or by performing a Si supply process to the crystalline oxide semiconductor film and then forming a first insulating film in contact with the crystalline oxide semiconductor film (first insulating film forming step). The average silicon concentration of the crystalline oxide semiconductor film can be adjusted to 1.5 to 10 at % by the Si supply process to the crystalline oxide semiconductor film.

A method of forming an oxide thin film containing an oxide of In as a main component is not particularly limited, but examples thereof include DC sputtering, AC sputtering, RF sputtering, ICP sputtering, reactive sputtering, ion plating, ALD, PLD, MO-CVD, ICP-CVD, a sol-gel method, a coating method, and mist CVD.

When the film formation is performed by sputtering, the film formation may be performed by a device with a planar sputtering cathode or may be performed by a device with a rotary sputtering cathode.

As an example of the method of forming the oxide thin film, the film may be produced by performing film formation by DC sputtering through use of a sputtering target including an oxide sintered body containing an oxide of In as a main component.

The atomic composition ratio of the oxide thin film obtained by the sputtering method reflects the atomic composition ratio of the oxide sintered body in the sputtering target. Accordingly, the film formation is preferably performed by using a sputtering target including an oxide sintered body having the same atomic composition ratio as the atomic composition ratio of a desired oxide thin film.

In addition, heat treatment may be performed after the formation of the oxide thin film. The step of the heat treatment is not particularly limited, but a hot air furnace, an IR furnace, a lamp annealing device, a laser annealing device, a thermal plasma device, or the like may be used.

Further, plasma oxidation treatment with N₂O or plasma oxidation treatment with O₂ may be performed after the annealing. A device for the plasma oxidation treatment is not particularly limited, but is, for example, PE-CVD.

The content of an impurity metal in the target used in the sputtering method is preferably 500 ppm or less, more preferably 100 ppm or less. The content of the impurity metal in the target may be measured by ICP or SIMS as in the crystalline oxide semiconductor film. The “impurity” contained in the target means a trace element that is mixed in a raw material or during a manufacturing process and is not intentionally added, the element having substantially no influence on the performance of each of the target and the semiconductor. The term “impurity metal” means a metal element among the elements as “impurities.”

In this embodiment, the sputtering target may consist essentially of In and an element selected from Mg, Al, Si, Zn, Ga, Mo, Sn, lanthanoid elements (Ln elements), and O. Herein, the term “essentially” means that the sputtering target may contain any other component in addition to In described above to the extent that the effects of the present disclosure attributed to the combination of Mg, Al, Si, Zn, Ga, Mo, Sn, Ln, and O are exhibited.

As in the crystalline oxide semiconductor film of the laminate structure of the present disclosure described above, the sputtering target according to a more preferred first mode of this embodiment is an oxide consisting of In and Ga as metal elements, and the atomic ratios satisfy the following formula (11).

$$[ Ga ] / ( [ ln ] + [ Ga ] ) < 22 at \% \qquad ( 11 )$$

The sputtering target according to a more preferred second mode is an oxide consisting of In and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as metal elements, and when the metal element except In is represented by X, the atomic ratios satisfy the following formula (12).

$$[ X ] / ( [ ln ] + [ X ] ) < 15 at \% \qquad ( 12 )$$

The sputtering target according to a more preferred third mode is an oxide consisting of In, Ga, and one or more elements X selected from B, Al, Sc, Mg, Zn, Ti, Y, Zr, Mo, Sn, Hf, W, Nb, Ta, Ge, Si, La, Ce, Pr, Nd, Sm, Dy, Ho, Er, Tm, Yb, and Lu as metal elements, and when the metal element except In and Ga is defined as an additive element X, the atomic ratios satisfy the following formulae (13) and (14).

$$[ Ga ] / ( [ ln ] + [ Ga ] + [ X ] ) < 22.5 at \% \qquad ( 13 )$$

$$[ X ] / ( [ ln ] + [ Ga ] + [ X ] ) < 8.0 at \% \qquad ( 14 )$$

The sputtering target according to a more preferred fourth mode is an oxide consisting of In, Sn, and one or more elements X selected from B, Al, Sc, Mg, Zn, Ti, Y, Zr, Mo, Hf, W, Nb, Ta, Ge, Si, La, Ce, Pr, Nd, Sm, Dy, Ho, Er, Tm, Yb, and Lu as metal elements, and when the metal element except In and Sn is defined as an element X, the atomic ratios satisfy the following formulae (15) and (16).

$$[ Sn ] / ( [ ln ] + [ Sn ] + [ X ] ) < 20 at \% \qquad ( 15 )$$

$$[ X ] / ( [ ln ] + [ Sn ] + [ X ] ) < 8. at \% \qquad ( 16 )$$

The sputtering target according to a more preferred fifth mode is an oxide consisting of In, Zn, and one or more elements X selected from B, Al, Sc, Mg, Ti, Y, Zr, Mo, Hf, W, Nb, Ta, Ge, Si, La, Ce, Pr, Nd, Sm, Dy, Ho, Er, Tm, Yb, and Lu as metal elements, and when the metal element except In and Zn is defined as an element X, the atomic ratios satisfy the following formulae (17) and (18).

$$[ Zn ] / ( [ ln ] + [ Zn ] + [ X ] ) < 12 at \% \qquad ( 17 )$$

$$[ X ] / ( [ ln ] + [ Zn ] + [ X ] ) < 8. at \% \qquad ( 18 )$$

In the sputtering target according to a preferred mode, the atomic ratio of In with respect to all metal elements contained in the sputtering target ([In]/([In]+[all metal elements except In])×100) is 62 at % or more.

In the sputtering target according to a preferred mode, the atomic ratio of Ga with respect to all metal elements contained in the sputtering target ([Ga]/([Ga]+[all metal elements except Ga])×100) (atomic %: at %) is 30 at % or less.

In the sputtering target according to a preferred mode, the total amount of the additive element Z (one or more kinds selected from B, AI, Si, Sc, Zn, Ge, Y, Zr, Sn, Sm, and Yb) with respect to all metal elements contained in the sputtering target ([total amount of additive element]/([total amount of additive element]+[all metal elements except additive element])×100) (atomic %: at %) is 10 at % or less.

The oxide thin film obtained by film formation by sputtering through use of the sputtering target containing indium oxide as a main component may be an amorphous oxide thin film. The amorphous oxide thin film is patterned into an island shape by photolithography, and is heated to be crystallized before the formation of a protective film. Thus, a crystalline oxide semiconductor film in which a surface crystal has a single crystal orientation can be obtained.

Respective steps are described below with the method of producing a laminate structure illustrated in FIG. 1 being used as an example.

The laminate structure of this embodiment may be produced, for example, by performing a step of forming an oxide thin film containing an oxide of In as a main component on a lower layer or the like for forming a TFT, such as a substrate, a buffer layer, or an insulating layer, and subjecting the oxide thin film to crystallization treatment to form a crystalline oxide semiconductor film (crystalline oxide semiconductor film formation step), and a step of forming a first insulating film in contact with the crystalline oxide semiconductor film, followed by heat treatment, to form a first insulating film (first insulating film formation step).

### [Crystalline Oxide Semiconductor Film Formation Step]

### (Formation of Oxide Thin Film)

In a step of forming an oxide thin film, an oxide thin film is formed by sputtering through use of the above-mentioned sputtering target and through use of, as a sputtering gas, one or more kinds of gases selected from the group consisting of: argon; and oxygen substantially free of impurity gases. In this step, it is preferred that the sputtering be performed by mounting the sputtering target on a RF magnetron sputtering device or a DC magnetron sputtering device.

The sputtering gas being “substantially free of impurity gases” means that impurity gases except the sputtering gas are not actively introduced, except for gases that are brought in by adsorbed water in association with the insertion of gases, and gases that cannot be eliminated (inevitable impurity gases), such as leakage from a chamber and adsorbed gases. Impurities are preferably eliminated from the gas (sputtering gas) to be introduced at the time of the film formation by sputtering, if possible.

The ratio of the impurity gases in the sputtering gas is preferably 0.1 vol % or less, more preferably 0.05 vol % or less. When the ratio of the impurity gases is 0.1 vol % or less, the crystallization of the oxide thin film progresses without any problem.

The purity of each of high-purity argon and high-purity oxygen, which are examples of the sputtering gas, is preferably 99 vol % or more, more preferably 99.9 vol % or more, still more preferably 99.99 vol % or more.

The gas (sputtering gas) to be introduced at the time of the film formation by sputtering is not particularly limited, but examples thereof include argon, nitrogen, oxygen, water, hydrogen, and a mixed gas containing two or more kinds of these gases.

An oxygen partial pressure in a mixed gas in the case of using argon and oxygen as an example is preferably more than 0 vol % and 50 vol % or less, more preferably more than 0 vol % and 20 vol % or less. When the oxygen partial pressure is more than 0 vol % and 50 vol % or less, the oxide thin film is easily crystallized to become a semiconductor at the time of heating. When the oxygen partial pressure is changed, the oxidation degree of the oxide thin film, that is, the crystallization degree thereof can be regulated. It is only required that the oxygen partial pressure be appropriately selected as required.

A water partial pressure in a mixed gas in the case of using argon and water as an example is preferably more than 0.03 vol % and 10 vol % or less, more preferably more than 0.03 vol % and 5 vol % or less. When the water partial pressure is more than 0.03 vol % and 5 vol % or less, the oxide thin film is easily crystallized to become a semiconductor at the time of heating. In addition, a mixed gas of hydrogen and oxygen may be used instead of water.

A crystal can be grown (to a columnar shape with respect to a lower layer, for example) by heating the oxide thin film obtained by sputtering film formation through a heat treatment step described later. When the crystalline oxide semiconductor film formed as described above is applied to a small TFT, the injection property of electron carriers becomes excellent at the time of driving, resulting in a high mobility.

### (Heat Treatment of Oxide Thin Film)

After the formation of the oxide thin film, heat treatment is performed. This heat treatment is sometimes referred to as “annealing.” The annealing treatment of the oxide thin film may be performed before the formation of a first insulating film described later or after the formation thereof, but it is preferred to perform the annealing treatment before the formation.

When the annealing is performed before the formation of the first insulating film, oxygen and hydrogen are diffused at the time of the annealing, and thus a high-quality columnar crystal is obtained. As a result, a small TFT with a low interfacial electron trap level and a high mobility is obtained after the formation of the first insulating film.

The temperature of the heat treatment of the oxide thin film is preferably 250° C. or more and 500° C. or less, more preferably 280° C. or more and 470° C. or less, still more preferably 300° C. or more and 450° C. or less.

When the heat treatment temperature after the formation of the oxide thin film is 250° C. or more, the oxide thin film is easily crystallized. When the heat treatment temperature after the formation of the oxide thin film is 500° C. or less, a crystal can be prevented from abnormally growing to form a large crystal grain, and the crystal grain diameter can be controlled to be small.

A heating time in the step of heat-treating the oxide thin film is preferably 0.1 hour or more and 5 hours or less, more preferably 0.3 hour or more and 3 hours or less, still more preferably 0.5 hour or more and 2 hours or less.

Even when the heating time in the heat treatment step is less than 0.1 hour, the crystallization of the oxide thin film progresses to some extent. However, when the heating time is 0.1 hour or more, atomic diffusion easily progresses in the oxide thin film, and the oxide thin film is easily stabilized after the crystallization. Thus, a stable crystalline oxide semiconductor film is easily obtained.

When the heating time in the heat treatment step is 5 hours or less, the heat treatment step is excellent in economic efficiency.

The term “heating time” means a time (retention time) for which a predetermined highest temperature is maintained during the heat treatment.

A rate of temperature increase in the step of heat-treating the oxide thin film is preferably 2° C./min or more and 40° C./min or less, more preferably 3° C./min or more and 20° C./min or less.

When the rate of temperature increase in the step of heat-treating the oxide thin film is 2° C./min or more, the production efficiency of the oxide thin film is increased as compared to a case where the rate of temperature increase is less than 1° C./min.

When the rate of temperature increase in the step of heat-treating the oxide thin film is 40° C./min or less, at the time of the crystallization, the metal elements are uniformly diffused, and crystals in which no metal is segregated at the grain boundaries can be formed.

In addition, the rate of temperature increase in the heat treatment step is different from a value calculated from the set temperature and set time of a furnace, and is a value obtained by dividing the actual temperature of the oxide thin film by a time. The actual temperature of the oxide thin film may be determined, for example, by measuring an area within 1 cm from the oxide thin film in the furnace with a thermocouple.

The step of heat-treating the oxide thin film is preferably performed under an atmospheric atmosphere having a humidity of 10% or more at 25° C. When the heat treatment step is performed in the atmosphere having a humidity of 10% or more, hydrogen and oxygen are diffused into the film at the time of the annealing, and thus the crystallization can be accelerated.

The step of heat-treating the oxide thin film is preferably performed after the patterning of the oxide thin film. When the heat treatment is performed after the patterning, the crystallization of the oxide thin film can be accelerated while excess oxygen existing in the film during the film formation and organic substances adhering during the patterning are desorbed. As a result, a film having no organic substances or excess oxygen and having few crystal defects in the crystal grains can be formed, and an oxide thin film having few electron traps and a satisfactory conduction characteristic can be formed.

Crystal defects in the film after the step of heat-treating the oxide thin film may be evaluated, for example, by defect analysis such as cathodoluminescence (CL). When there are a large number of defects derived from oxygen, a light emission of 680 nm is strongly detected. In order to obtain an oxide thin film having few electron traps and a satisfactory conduction characteristic, it is required to adjust the film formation method and the annealing conditions so as to provide film quality in which the light emission based on the CL is prevented from being detected to the extent possible.

The step of heat-treating the oxide thin film may be performed a plurality of times. For example, the heat treatment step described above (first heat treatment step) may be performed after the patterning of the oxide thin film, and further a heat treatment step (second heat treatment step) may be performed as a final step after the production of a TFT element. The second heat treatment step is preferably performed at an annealing temperature higher than that in the first heat treatment step.

### (Supply of Si to Crystalline Oxide Semiconductor Film)

As described below, when annealing (heat treatment) the first insulating film to diffuse Si into the crystalline oxide semiconductor film from the first insulating film side, it is preferable that the film thickness of the oxide thin film (crystalline oxide semiconductor film) is less than 50 nm. By having a film thickness of less than 50 nm, it is easy to obtain a state in which silicon (Si) is appropriately diffused into the crystalline oxide semiconductor film from the first insulating film side during the annealing treatment of the first insulating film described below, and a crystalline oxide semiconductor film having the above-mentioned average silicon concentration can be stably obtained.

The thickness of the oxide thin film (crystalline oxide semiconductor film) is preferably 42 nm or less, more preferably 32 nm or less, more preferably 30 nm or less, more preferably 20 nm or less, even more preferably 15 nm or less, even more preferably 11 nm or less, and particularly preferably 10 nm or less. On the other hand, the thickness of the oxide thin film (crystalline oxide semiconductor film) is, for example, 3 nm or more, may be 4 nm or more, may be 5 nm or more, or may be 8 nm or more. By setting the thickness to 3 nm or more, it is possible to grow high-quality crystals without being affected by the underlayer during the annealing treatment of the oxide film described later.

Note that when a technique such as ion implantation, which will be described later, is used to supply Si to the crystalline oxide semiconductor film, the film thickness of the oxide thin film (crystalline oxide semiconductor film) does not necessarily have to be less than 50 nm.

In that case, the film thickness of the oxide thin film (crystalline oxide semiconductor film) may be, for example, 50 nm or more, 100 nm or more, or 200 nm or more, or may be 500 nm or less, 400 nm or less, or 300 nm or less.

A typical method for adjusting the average silicon concentration of the crystalline oxide semiconductor film to the above-mentioned predetermined range is to heat-treat (anneal) the first insulating film formed by sputtering and containing a silicon (Si)-containing compound as a main component. The method for heat-treating the first insulating film is as described below in the section on heat-treating the first insulating film. By employing of the heat-treatment, silicon (Si) diffuses from the first insulating film side into the crystalline oxide semiconductor film during the annealing of the first insulating film, and a crystalline oxide semiconductor film having the above-mentioned average silicon concentration is obtained.

In this method, the thickness of the oxide thin film formed in the oxide thin film formation step (thickness of the crystalline oxide semiconductor film) is preferably less than 50 nm, as described above. This makes it easier to obtain a state in which silicon (Si) is appropriately diffused into the crystalline oxide semiconductor film from the first insulating film side during annealing of the first insulating film, and a crystalline oxide semiconductor film having the above-mentioned average silicon concentration can be stably obtained.

Note that this method may also be used in conjunction with a Si supply method described later as appropriate.

The method of adjusting the average silicon concentration of the crystalline oxide semiconductor film to the above-mentioned predetermined range is not limited to the above-mentioned typical example, and may be, for example, a method of forming a first insulating film containing a silicon (Si)-containing compound as a main component at a predetermined temperature by chemical vapor deposition (CVD). The method of forming the first insulating film by chemical vapor deposition (CVD) is as described later in the film formation of the first insulating film. By employing this method, during the film formation or heat treatment of the first insulating film, silicon (Si) diffuses into the crystalline oxide semiconductor film from the first insulating film side, and a crystalline oxide semiconductor film having the above-mentioned average silicon concentration is obtained.

In this method, it is not necessary to perform a heat treatment (annealing treatment) of the first insulating film, but from the viewpoint of smoothly diffusing silicon (Si) from the first insulating film side into the crystalline oxide semiconductor film, it is preferable to perform a heat treatment (annealing treatment) of the first insulating film.

In this method, as described above, it is preferable that the film thickness of the oxide thin film formed in the oxide thin film formation step (film thickness of the crystalline oxide semiconductor film) is less than 50 nm.

Note that this method may also be used in conjunction with a Si supplying method described later as appropriate.

In addition to the typical examples described above, methods for adjusting the average silicon concentration of the crystalline oxide semiconductor film to the above-mentioned predetermined range include a method of performing a process for supplying silicon atoms to the crystalline oxide semiconductor film (Si supply process).

Examples of the Si supply process include a method of forming a film containing a silicon (Si)-containing compound as a main component by sputtering or CVD so as to be in direct contact with the crystalline oxide semiconductor film to form a film as a Si supply source on the crystalline oxide semiconductor film, or a method of ion-implanting silicon atoms as Si cations into the crystalline oxide semiconductor film.

When forming a film as a Si supply source by sputtering, the film as a Si supply source can be formed by the same method as the formation of the first insulating film (formation of first insulating film and heat treatment) described below. By this, silicon (Si) is supplied into the crystalline oxide semiconductor film during sputtering of the film as a Si supply source, and a crystalline oxide semiconductor film having the above-mentioned average silicon concentration is obtained.

When forming a film as a Si supply source by sputtering, a target containing a silicon (Si)-containing compound (e.g., SiO₂, SiNₓ, silicon oxynitride, etc.) as a main component may be used as the sputtering target, or a Si target may be used.

The thickness of the film serving as the Si supply source is, for example, 4 nm or more, may be 8 nm or more, or may be 90 nm or more. The upper limit of the thickness of the film serving as the Si supply source is not particularly limited, but may be, for example, 120 nm or less, may be 50 nm or less, or may be 20 nm or less.

When the thickness of the film serving as the Si supply source is in the above range, silicon (Si) is appropriately supplied into the crystalline oxide semiconductor film during sputtering deposition of the film, and a crystalline oxide semiconductor film having the above-mentioned average silicon concentration can be stably obtained. In addition, when the thickness of the film serving as the Si supply source is in the above range, a stable device shape can be obtained when the laminate structure of the aspect is applied to a TFT.

In the method of forming a film as a Si supply source by sputtering, the film as a Si supply source does not necessarily need to be heat-treated (annealed), but by performing heat treatment after the film is sputtered, the silicon (Si) contained in the film is diffused into the crystalline oxide semiconductor film. This makes it possible to stably obtain a crystalline oxide semiconductor film having the above-mentioned average silicon concentration.

Note that the film as a Si supply source formed by this method may be, for example, a layer that constitutes part or all of the gate insulating film 24 in a TFT, but the film as a Si supply source may also be a layer other than a gate insulating film, for example, a layer formed as a protective film or a buffer layer.

When a first insulating film is formed after performing this method, the film as a Si supply source and the first insulating film formed thereafter typically function as the gate insulating film of the final TFT.

When a first insulating film is formed after performing this method, it is preferable to perform a heat treatment of the first insulating film.

When the average silicon concentration of the crystalline oxide semiconductor film is adjusted by this method, it is preferable that the film thickness of the crystalline oxide semiconductor film (oxide thin film) is less than 50 nm.

When the film as the Si supply source is formed by CVD, the film as the Si supply source can be formed by the same method as the first insulating film formed by CVD, which will be described later in the section on formation of the first insulating film. By this method, silicon (Si) is supplied into the crystalline oxide semiconductor film during CVD formation of the film as the Si supply source, and a crystalline oxide semiconductor film having the above-mentioned average silicon concentration is obtained.

The film thickness of the film as the Si supply source may be, for example, 8 nm or more, or 90 nm or more. The upper limit of the film thickness of the film as the Si supply source is not particularly limited, but may be, for example, 120 nm or less, 50 nm or less, or 20 nm or less.

When the film thickness of the film as the Si supply source is in the above range, silicon (Si) is appropriately supplied into the crystalline oxide semiconductor film during CVD formation of the film as the Si supply source, and a crystalline oxide semiconductor film having the above-mentioned average silicon concentration can be stably obtained. In addition, when the film thickness of the film as the Si supply source is in the above range, a stable device shape can be obtained when the laminate structure of the aspect is applied to a TFT.

In the method of forming a film as a Si supply source by CVD deposition, the film as a Si supply source does not necessarily need to be heat-treated (annealed). However, by performing heat treatment after the CVD deposition of the film, silicon (Si) contained in the film is diffused into the crystalline oxide semiconductor film. This allows a crystalline oxide semiconductor film having the above-mentioned average silicon concentration to be stably obtained.

Note that the film as a Si supply source formed by this method may be a layer that constitutes part or all of the gate insulating film 24 in a TFT, but the film as a Si supply source may also be a layer other than a gate insulating film, for example, a layer formed as a protective film or buffer layer.

When the first insulating film is formed after performing this method, the film as a Si supply source and the first insulating film formed thereafter typically function as the gate insulating film of the TFT to be finally obtained.

When the first insulating film is formed after performing this method, it is preferable to perform heat treatment of the first insulating film.

Furthermore, when adjusting the average silicon concentration of the crystalline oxide semiconductor film by this method, it is preferable that the film thickness of the crystalline oxide semiconductor film (oxide thin film) is less than 50 nm.

When performing a Si supply process by ion-implanting silicon atoms as Si cations into the crystalline oxide semiconductor film or the first insulating film, the dose of Si cations into the crystalline oxide semiconductor film may be 0.01×10¹⁶ ions/cm² to 50×10¹⁶ ions/cm², may be 0.1×10¹⁶ ions/cm² to 20×10¹⁶ ions/cm², may be 0.3×10¹⁶ ions/cm² to 10×10¹⁶ ions/cm², or may be 0.5×10¹⁶ ions/cm² to 15×10¹⁶ ions/cm².

By setting the dose of Si cations into the crystalline oxide semiconductor film within the above range, a crystalline oxide semiconductor film having the above-mentioned average silicon concentration can be stably obtained.

When the Si supply process is performed by ion-implanting silicon atoms as Si cations into the crystalline oxide semiconductor film, the amount of implantation energy may be 0.1 keV to 1000 keV, may be 1 keV to 100 keV, or may be 5 keV to 50 keV.

When the first insulating film or the crystalline oxide semiconductor film is subjected to an ion implantation process of silicon atoms (Si cations), the average silicon concentration of the crystalline oxide semiconductor film can be set to the above-mentioned range by the process. Therefore, when the ion implantation process of silicon atoms (Si cations) is performed, it is not necessary to perform a heat treatment of the first insulating film.

When the ion implantation process of silicon atoms (Si cations) is performed, the film thickness of the crystalline oxide semiconductor film (oxide thin film) does not have to be less than 50 nm. That is, when the ion implantation process of silicon atoms (Si cations) is performed, the average silicon concentration of the crystalline oxide semiconductor film can be set to the above-mentioned range even if the film thickness of the crystalline oxide semiconductor film (oxide thin film) is 50 nm or more.

### [First Insulating Film Formation Step]

The insulating film may be the film formed in the above-mentioned Si supply treatment for the crystalline oxide semiconductor film or may be separately formed on the film formed in the above-mentioned Si supply treatment. The film formed in the above-mentioned Si supply treatment and the insulating film separately formed thereon function as the gate insulating film 24 in a TFT.

### (Formation of First Insulating Film)

A method of forming the first insulating film is not particularly limited. Examples of the production method include PE-CVD, ALD, PLD, MO-CVD, RF sputtering, ICP sputtering, reactive sputtering, ICP-CVD, ion plating, a sol-gel method, a coating method, and mist CVD. Tetraethoxysilane (TEOS) may be used as the kind of gas in the PE-CVD in addition to silane (SiH₄).

When the first insulating film is formed by sputtering, a target containing a silicon (Si)-containing compound (e.g., SiO₂, SiNₓ, or silicon oxynitride) as a main component is typically used as a sputtering target. It is preferred that one or more kinds of gases selected from the group consisting of: argon; and oxygen substantially free of impurity gases be used as a sputtering gas in the same manner as in the formation of the oxide thin film described above.

The suitable ranges of the ratio of impurity gases in the sputtering gas and the degree of purity of high-purity argon and high-purity oxygen in the sputtering gas are the same as the suitable ranges in the formation of the oxide thin film described above.

The gas (sputtering gas) to be introduced at the time of the film formation by sputtering is not particularly limited, but examples thereof include argon, nitrogen, oxygen, water, hydrogen, and a mixed gas containing two or more kinds of these gases.

An oxygen partial pressure in a mixed gas in the case of using argon and oxygen as an example is preferably more than 0 vol % and 50 vol % or less, more preferably more than 0 vol % and 40 vol % or less. The atomic ratio of silicon (Si) with respect to all the atoms contained in the first insulating film may be adjusted by changing the oxygen partial pressure. It is only required that the oxygen partial pressure be appropriately selected as required.

When the first insulating film is formed by chemical vapor deposition (CVD), the temperature during the CVD process is preferably 240° C. or more and 500° C. or less, more preferably 280° C. or more and 470° C. or less, and even more preferably 300° C. or more and 450° C. or less.

If the temperature during the CVD process is within the above range, diffusion of silicon (Si) contained in the first insulating film into the crystalline oxide semiconductor film tends to proceed smoothly, and a crystalline oxide semiconductor film having the above-mentioned average silicon concentration can be stably obtained.

Note that the temperature during the CVD process means the temperature of the substrate in the CVD apparatus.

### (Heat Treatment of First Insulating Film)

After the first insulating film is formed, a heat treatment (annealing treatment) is performed. When the first insulating film contains a silicon (Si)-containing compound (e.g., SiO₂, SiNₓ, silicon oxynitride, etc.) as a main component, the silicon (Si) contained in the first insulating film is diffused into the crystalline oxide semiconductor film by performing a heat treatment (annealing treatment) after the formation of the first insulating film. This results in a crystalline oxide semiconductor film having the above-mentioned average silicon concentration.

Regarding Si, which is a positive tetravalent element, if the amount of Si contained in advance in the sintered body (target) used for sputtering film formation of the crystalline oxide semiconductor exceeds 0.1%, the resistance of the sintered body may increase or it may become difficult to increase the density of the sintered body. Therefore, from the viewpoint of maintaining the original function of the crystalline oxide semiconductor film, the amount of Si that can be contained in the oxide thin film at the film formation step by sputtering from the sintered body (target) is limited, but by supplying silicon atoms into the crystalline oxide semiconductor film from the first insulating film side formed after the formation of the crystalline oxide semiconductor film, the stability of the crystalline oxide semiconductor film can be increased without impairing the original function thereof.

In addition, when the heat treatment (annealing treatment) is performed after the formation of the first insulating film, hydrogen contained in the first insulating film diffuses to the crystalline oxide semiconductor film, and crystal defects that exist on the surface of the crystalline oxide semiconductor film are terminated by a hydroxy group. As a result, a crystalline oxide semiconductor film having few electron traps and a satisfactory conduction characteristic can be formed.

The temperature of the heat treatment after the formation of the first insulating film is preferably 250° C. or more and 500° C. or less, more preferably 280° C. or more and 470° C. or less, and even more preferably 300° C. or more and 450° C. or less.

If the heat treatment temperature after the formation of the first insulating film is within the above range, diffusion of silicon (Si) contained in the first insulating film into the crystalline oxide semiconductor film tends to proceed smoothly, and a crystalline oxide semiconductor film having the above-mentioned average silicon concentration can be stably obtained.

The heating time in the heat treatment step after the formation of the first insulating film is preferably 0.1 hour or more and 5 hours or less, more preferably 0.3 hour or more and 3 hours or less, still more preferably 0.5 hour or more and 2 hours or less.

When the heating time in the heat treatment step after the formation of the first insulating film is 0.1 hour or more, silicon (Si) contained in the first insulating film can be satisfactorily diffused into the crystalline oxide semiconductor film, so that the crystalline oxide semiconductor film having the above-mentioned average silicon concentration can be obtained stably.

When the heating time in the heat treatment step after the formation of the first insulating film is 5 hours or less, the heat treatment step is excellent in economic efficiency.

The rate of temperature increase in the heat treatment step after formation of the first insulating film is preferably 2° C./min or more and 40° C./min or less, and more preferably 3° C./min or more and 20° C./min or less.

If the rate of temperature increase in the heat treatment step after formation of the first insulating film is within the above range, diffusion of silicon (Si) contained in the first insulating film into the crystalline oxide semiconductor film tends to proceed smoothly, and a crystalline oxide semiconductor film having the above-mentioned average silicon concentration can be stably obtained.

The method for determining the rate of temperature increase in the heat treatment step after formation of the first insulating film is the same as the method for determining the rate of temperature increase in the heat treatment step of the oxide film described above.

The heat treatment step after the formation of the first insulating film is preferably performed in an air atmosphere with a humidity of 10% or more at 25° C. When the heat treatment step is performed in air with a humidity of 10% or more, silicon (Si) contained in the first insulating film is likely to diffuse smoothly into the crystalline oxide semiconductor film.

The above-mentioned first insulating film forming step and the first insulating film heat treatment step may be performed only once, or the film forming and heat treatment steps may be performed multiple times. In this case, the film thicknesses formed in each film forming step may be the same or different.

Next, a method for producing the laminate structure shown in FIG. 2 will be described.

In the laminate structure shown in FIG. 2, a second insulating film is first formed on the lower layers constituting the TFT, such as a substrate, a buffer layer, and an insulating layer. The second insulating film can be formed by the same method as the process for forming the first insulating film (formation and heat treatment of the first insulating film). The subsequent formation of the crystalline oxide semiconductor film and the first insulating film can be performed by carrying out the same method as described in the method for producing the laminate structure shown in FIG. 1, with the second insulating film as the lower layer.

### 3. Thin Film Transistor (TFT)

A TFT according to this aspect has the above-mentioned laminate structure of the present disclosure.

In one embodiment, the TFT includes a buffer layer, a channel layer laminated on the buffer layer in contact therewith, a source electrode and a drain electrode each connected to the channel layer, and a gate electrode laminated on the channel layer through intermediation of a gate insulating film. The channel layer is a crystalline oxide semiconductor film included in the laminate structure of the present disclosure, the gate insulating film is a first insulating film included in the laminate structure of the present disclosure and the buffer layer is the above-mentioned second insulating film.

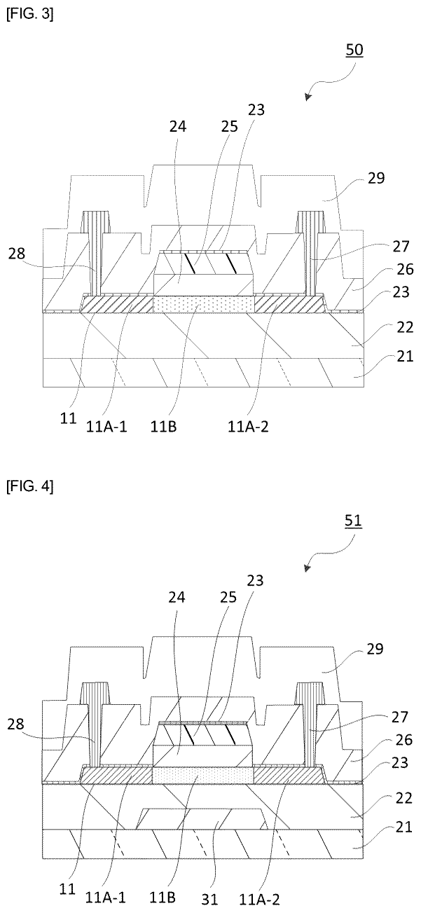

In FIG. 3 and FIG. 4 described later, there is illustrated a configuration in which both end sides of the channel layer, that is, the vicinities of regions to which the source electrode and the drain electrode are connected are low-resistance regions A of the crystalline oxide semiconductor film, and a region in contact with a lower surface of the gate insulating film is a high-resistance region B. That is, there is illustrated a configuration in which the gate insulating film is formed on the high-resistance region B, and the source electrode and the drain electrode are formed on the low-resistance regions A.

As the configuration of the TFT according to this embodiment, for example, a configuration known in the related art may be adopted.

The TFT according to this aspect may be produced by adopting the method of producing a laminate structure described above. That is, the production method includes: a crystalline oxide semiconductor film formation step including a step of forming an oxide thin film by sputtering through use of a sputtering target and one or more kinds of gases selected from the group consisting of: argon; nitrogen; hydrogen; water; and oxygen substantially free of impurity gases as a sputtering gas (sometimes referred to as “step of forming an oxide thin film”) and a step of subjecting the oxide thin film to heat treatment (sometimes referred to as “step of heat-treating the oxide thin film”); and an insulating film formation step including a step of forming an insulating film on the crystalline oxide semiconductor film by sputtering through use of a sputtering target containing, for example, silicon as a main component (sometimes referred to as “step of forming an insulating film”) and a step of subjecting the insulating film to heat treatment (sometimes referred to as “step of heat-treating the insulating film”). Conditions and the like for each of the film formation steps and each of the heat treatment steps are as described above. A source electrode, a drain electrode, a gate electrode, and a gate insulating film may be formed by known materials and formation methods.

In the laminate structure according to one embodiment, the crystalline oxide semiconductor film has a high mobility and is excellent in stability. When the laminate structure including such crystalline oxide semiconductor film is used as a channel layer of a TFT, a high mobility and high reliability with suppressed threshold voltage (Vth) fluctuations are obtained.

Herein, the mobility at the time of the application of a Vd of 20 V is defined as a saturation mobility. Specifically, a transmission characteristic Id-Vg graph at the time of the application of a Vd of 20 V is created, and a transconductance (Gm) at each Vg is calculated. The calculation may be performed by determining the mobility through use of the formula of a saturation region.

In the following description, the current Id is a current between the source electrode and the drain electrode. The voltage Vd is a voltage (drain voltage) applied between the source electrode and the drain electrode. The voltage Vg is a voltage (gate voltage) applied between the source electrode and the gate electrode.

The shape of the thin film transistor according to this aspect is not particularly limited, but the thin film transistor is preferably a top-gate type transistor, a back channel etch type transistor, an etch stopper type transistor, or the like. In addition, those transistors may be self-aligned transistors.

Embodiments of the present disclosure are described below with reference to the drawings and the like. It should be easily understood by a person skilled in the art that the embodiments may be carried out in various manners, and their forms and details may be variously modified without departing from the gist and scope of the present disclosure. Accordingly, the present disclosure is not interpreted to be limited to the descriptions in the embodiments below.

In the drawings, a size, a layer thickness, a region, and the like are sometimes exaggerated for clarification. Accordingly, the present disclosure is not limited to the size, the layer thickness, the region, and the like shown in the drawings. The drawings include schematic illustrations of an ideal example, and the present disclosure is not limited to shapes, values, and the like shown in the drawings.

FIG. 3 is a schematic sectional view of an example of the TFT of this aspect.

A TFT 50 is a top-gate type TFT, and includes a substrate 21, a buffer layer (second insulating layer) 22, a channel layer (crystalline oxide semiconductor film) 11, an ITO layer 23, the gate insulating film (first insulating film) 24, a gate electrode 25, an interlayer insulating film 26, a source electrode 27, a drain electrode 28, and a protective film 29.

The TFT 50 has a structure in which the substrate 21, the buffer layer 22 (second insulating layer), and the channel layer (crystalline oxide semiconductor film) 11 are laminated in the stated order. A high-resistance region 11B is present in the center portion of the channel layer 11, and the gate insulating film 24 and the gate electrode 25 are laminated on the high-resistance region 11B in the stated order. The gate insulating film 24 is an insulating film that interrupts conduction between the gate electrode 25 and the crystalline oxide semiconductor film 11.

Low-resistance regions 11A-1 and 11A-2 of the channel layer 11 are present on both sides of the high-resistance region 11B. The low-resistance regions 11A-1 and 11A-2 and the gate electrode 25 are covered with the ITO layer 23 and the interlayer insulating film 26. The ITO layer 23 is used at the time of the formation of the low-resistance regions of the channel layer 11.

Specifically, the low-resistance regions 11A-1 and 11A-2 are formed by causing a target portion of the channel layer 11 to have low resistance by performing heat treatment (annealing) in the presence of the ITO layer 23. A region that is not covered by the ITO layer 23 is maintained as the high-resistance region B.

The source electrode 27 and the drain electrode 28 are connected to the low-resistance regions 11A-1 and 11A-2, respectively, through contact holes formed in the ITO layer 23 and the interlayer insulating film 26. The source electrode 27 and the drain electrode 28 are conductive terminals for allowing a source current and a drain current to flow to the channel layer 11.

The protective film 29 is arranged so as to cover the TFT constituent layers, such as the interlayer insulating film 26, the source electrode 27, and the drain electrode 28.

The TFT of this embodiment may be modified with a known configuration.

For example, although not shown in FIG. 3, a light shield layer 31 may be formed between the substrate 21 and the buffer layer 22 in the TFT 50 as illustrated in FIG. 4, or the light shield layer 31 may be formed as an intermediate layer of the buffer layer 22 in which a plurality of layers are laminated.

FIG. 4 is a schematic sectional view of another example of the TFT of this aspect.

A TFT 51 has the same configuration as that of the TFT 50 except that the light shield layer 31 is arranged between the substrate 21 and the buffer layer 22. The light shield layer 31 is formed in order to suppress the malfunction of the TFT caused by light. The light shield layer may be connected to the source electrode 27 or may be connected to the gate electrode 25.

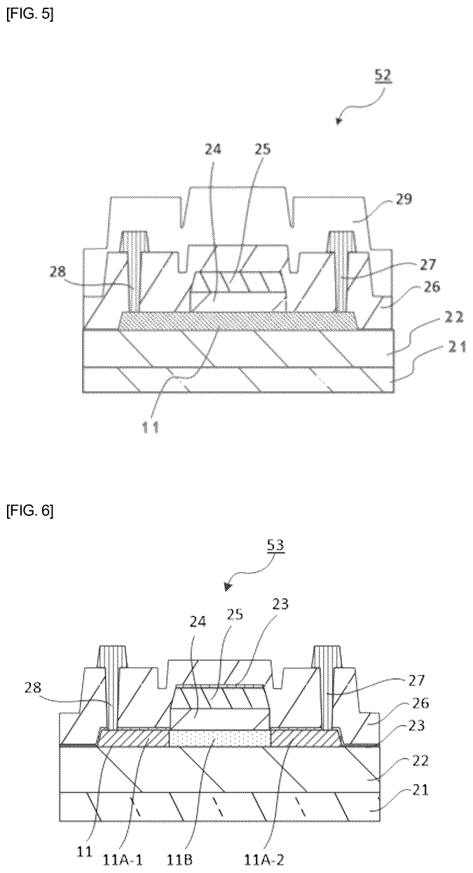

In addition, in FIG. 3, as an example of the TFT of the present disclosure, there is illustrated a configuration example in which both end sides of the channel layer 11, that is, the vicinities of the regions to which the source electrode 27 and the drain electrode 28 are connected are the low-resistance regions 11A of the crystalline oxide semiconductor film, and the region in contact with the lower surface of the gate insulating film 24 is the high-resistance region 11B. However, the TFT of the present disclosure is not limited to this configuration. That is, the TFT of the present disclosure may use a crystalline oxide semiconductor film having a uniform resistance value in a planar direction as the channel layer 11. In this case, the ITO layer 23 may not be formed as illustrated in FIG. 5.

FIG. 5 is a schematic sectional view of another example of the TFT of this embodiment.

A TFT 52 has the same configuration as that of the TFT 50 except that: the channel layer (crystalline oxide semiconductor film) 11 is a layer having no boundary of a resistance value (the channel layer (crystalline oxide semiconductor film) 11 is not divided into the low-resistance regions 11A and the high-resistance region 11B); and the ITO layer 23 is not formed.

In this embodiment, when the TFT is a small TFT, the crystalline oxide semiconductor film serving as the channel layer with respect to the source electrode and the drain electrode has a channel length (L length; length in the source electrode 27 and drain electrode 28 direction in a contact region between the channel layer 11 and the gate insulating layer 24 in FIG. 3) of 1 μm or more and 50 μm or less and a channel width (W length; length in a direction perpendicular to the source electrode 27 and drain electrode 28 direction in the contact region between the channel layer 11 and the gate insulating layer 24 in FIG. 3) of 1 μm or more and 80 μm or less.

The TFT of this embodiment may be modified with a known configuration.

A material for forming the substrate is not particularly limited, and any material that is generally used may be selected. There may be used, for example, a glass substrate, a ceramic substrate, a quartz substrate, or a sapphire substrate. In addition, for example, a single crystal semiconductor substrate, such as silicon or silicon carbide, a polycrystal semiconductor substrate, a compound semiconductor substrate such as silicon germanium, or a silicon on insulator (SOI) substrate may be applied, or these substrates each having a semiconductor element arranged thereon may be used as the substrate.

In addition, a flexible substrate may be used as the substrate. As a method of arranging the TFT on the flexible substrate, there is given a method of directly producing the TFT on the flexible substrate, and there is also given a method involving producing the TFT on a non-flexible substrate, then peeling the TFT, and setting the TFT on the flexible substrate. In this case, a release layer may be arranged between the non-flexible substrate and the TFT.

The buffer layer 22 may be formed of a single layer or two or more layers. In addition, a metal layer may be formed between the buffer layer 22 and the substrate 21.

It is preferred that the channel layer 11 and the buffer layer 22 be in direct contact with each other as illustrated in FIG. 3, and the buffer layer 22 directly contacted with the channel layer 11 corresponds to a second insulating film.

When there are two or more buffer layers 22, the layer of the buffer layers 22 that is in direct contact with the channel layer (crystalline oxide semiconductor film) 11 is the second insulating film.

The material for forming the buffer layer that is in direct contact with the channel layer (crystalline oxide semiconductor film) 11 can be used the same as that described for the second insulating film.

A material for forming the buffer layer that is not directly contacted with the channel layer (crystalline oxide semiconductor film) 11 is not particularly limited, and any material that is generally used may be selected. In addition, a laminated film may be used as the buffer layer. There may be used, for example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN. The oxidation numbers of the respective materials may be varied.

The light shield layer 31 may be connected to the source electrode 27 or may be connected to the gate electrode 25.

A material for forming the light shield layer is not particularly limited, and any material that is generally used may be selected. Specific examples thereof include metal electrodes made of Al, Ag, Cu, Cr, Ni, Co, Mo, Au, Ti, Zr, Ru, Y, Nb, Ta, and W, and metal electrodes made of alloys containing two or more kinds of these metals. In addition, a laminated electrode of two or more layers may be used.

In FIG. 4, a second buffer layer may be arranged between the light shield layer 31 and the substrate 21. A material for forming the second buffer layer is also not particularly limited, and any material that is generally used may be selected. In addition, a laminated film may be used as the second buffer layer. As a material for the second buffer layer, there may be used, for example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN. The oxidation numbers of the respective materials may be varied.

The material described as a material for the first insulating film may be used as a material for forming the gate insulating film.

Materials for forming the drain electrode, the source electrode, and the gate electrode are not particularly limited, and any materials that are generally used may be selected. Specifically, for example, there are given transparent electrodes made of ITO, IZO, ZnO, and SnO₂, metal electrodes made of Al, Ag, Cu, Cr, Ni, Co, Mo, Au, Ti, Zr, Ru, Y, Nb, Ta, and W, or metal electrodes made of alloys containing two or more kinds of these metals. In addition, a laminated electrode of two or more layers may be used.

A material for each interlayer insulating film is also not particularly limited, and any material that is generally used may be selected. In addition, a laminated film may be used as the interlayer insulating film.

For example, SiO₂, SiNₓ, silicon oxynitride, Al₂O₃, Ta₂O₅, TiO₂, MgO, ZrO₂, Ga₂O₃, GeO₂, Nd₂O₃, La₂O₃, CeO₂, K₂O, Li₂O, Na₂O, Rb₂O, Sc₂O₃, Y₂O₃, HfO₂, CaHfO₃, PbTiO₃, BaTa₂O₆, SrTiO₃, Sm₂O₃, or AlN may be used. The oxidation number of the respective materials may be varied.

Irrespective of the structure of the TFT, the protective film is preferably arranged on the drain electrode, the source electrode, and the conductive region. When the protective film is arranged, the TFT is easily improved in durability even when driven for a long period of time.

A method of producing an insulating films such as the buffer layer, the gate insulating film, or the interlayer insulating film is not particularly limited. Examples of the production method include PE-CVD, ALD, PLD, MO-CVD, RF sputtering, ICP sputtering, reactive sputtering, ICP-CVD, ion plating, a sol-gel method, a coating method, and mist CVD. Tetraethoxysilane (TEOS) may be used as the kind of gas in the PE-CVD in addition to silane (SiH₄).

For example, when an insulating film is formed by the PE-CVD, the process may become a high-temperature process. In addition, the protective film or the insulating film often contains an impurity gas immediately after the film formation, and is hence preferably subjected to the heat treatment (annealing treatment). When the impurity gas is removed by the heat treatment, a stable protective film or insulating film is obtained, which makes it easy to form a highly durable TFT.

The saturation mobility of the TFT is preferably 10.0 cm²/V·s or more, or 20.0 cm²/V·s or more.

When the saturation mobility of the TFT is set to 10.0 cm²/V·s or more, a higher resolution, a higher frame rate, and a larger area of a display can be achieved.

The saturation mobility of the TFT is determined from transmission characteristics in the case of the application of a drain voltage of 20 V. A method of measuring the saturation mobility of the TFT is described in detail in Examples.

The threshold voltage (Vth) is preferably −3.0 V or more and 3.0 V or less, more preferably −2.0 V or more and 2.0 V or less, still more preferably −1.0 V or more and 1.0 V or less. When the threshold voltage (Vth) is −3.0 V or more and 3.0 V or less, the threshold voltage (Vth) can be corrected to Vth=0 V by installing a Vth correction circuit on the TFT. When the TFT thus obtained is installed into a panel, a display can be driven without uneven brightness and burn-in.

The threshold voltage (Vth) may be defined as a Vg when Id=10⁻⁹ A based on the graph of transmission characteristics.

An on-off ratio is preferably 10⁶ or more, more preferably 10⁷ or more, still more preferably 10⁸ or more. When the on-off ratio is 10⁶ or more, a liquid crystal display can be driven. When the on-off ratio is 10⁸ or more, an organic EL device having a large contrast can be driven. In addition, when the on-off ratio can be set to 10¹⁰ or more, and the off-current can be set to 10⁻¹² A or less, a display element excellent in low consumption that can be driven at a low frequency of about 1 Hz can be provided.

The on-off ratio is determined by setting an off-current value to a value of Id when Vd=10 V and Vg=−10 V and setting an on-current value to a value of Id when Vd=10 V and Vg=20 V to determine a ratio [on-current value/off-current value].

The off-current value is preferably 10⁻¹⁰ A or less, more preferably 10⁻¹¹ A or less, still more preferably 10⁻¹² A or less. When the off-current value is 10⁻¹⁰ A or less, an organic EL having a large contrast can be driven. In addition, when the TFT is used as a transfer transistor or a reset transistor for a CMOS image sensor, the retention time of an image can be lengthened, and sensitivity can be improved.

The TFT according to this embodiment may be suitably used for solar cells, liquid crystal elements, organic electroluminescence elements, inorganic electroluminescence elements, and other display elements, and power semiconductor elements, touch panels, and other electronic devices.

The thin film transistor according to this embodiment may be applied to various integrated circuits including a field effect transistor (MOSFET or MESFET), a logic circuit, a memory circuit, and a differential amplification circuit, and the various integrated circuits may be applied to an electronic device, an electric device, a vehicle, a power engine, and the like. Further, the thin film transistor according to this embodiment may be applied not only to the field effect transistor but also to an electrostatic induction transistor and a Schottky barrier transistor.

The thin film transistor according to this embodiment may be suitably used for a display device such as a portable or in-vehicle display device, a solid-state image sensor, and the like. Further, the thin film transistor according to this embodiment may also be suitably used as a transistor for a flat panel detector for an X-ray image sensor for medical use.

In addition, the crystalline oxide semiconductor film according to this embodiment may be applied to a Schottky diode, a resistance change type memory, and a resistive element.

### EXAMPLES

The present disclosure is specifically described by way of Examples. The present disclosure is not limited to Examples.

### [Production of Self-Aligned Top-Gate Structure Small TFT]

### Example 1

A thin film transistor (TFT) 53 illustrated in FIG. 6 was produced through the following steps. The TFT 53 has the same configuration as that of the TFT 50 illustrated in FIG. 3 except that the protective layer 29 is absent.

### (1) Formation of Buffer Layer 22

A SiOₓ layer (buffer layer 22) having a thickness of 300 nm was formed on an alkali-free glass substrate 21 (EAGLE XG manufactured by Coning Incorporated) having a diameter of 4 inches by sputtering through use of a sputtering target of SiO₂. Sputtering conditions are as described below. The buffer layer corresponds to the second insulating film.
Substrate temperature: 25° C.
Ultimate pressure: 8.5×10⁵ Pa
Atmospheric gas: Ar
Sputtering pressure (total pressure): 0.4 Pa
Input voltage: RF 300 W
Distance between substrate (S) and target (T): 70 mm

### (2) Formation of Oxide Thin Film

Next, a channel layer was formed by sputtering through use of an oxide sputtering target obtained from a raw material mixture having a loaded composition ratio shown in Table 1-1. A metal composition ratio (unit: at %) in the oxide sputtering target is shown in Table 1-1.

Film formation conditions in the sputtering and the thickness of the channel layer are shown in

Table 1-1. Sputtering conditions except those shown in Table 1-1 are as described below.
Substrate temperature: 25° C.
Ultimate pressure: 1.0×10⁴ Pa
Atmospheric gas: mixed gas of Ar and H₂O
Sputtering pressure (total pressure): 0.5 Pa
Input voltage: DC 300 W
Distance between substrate (S) and target (T): 70 mm

### (3) Formation of Channel Layer 11

Next, the oxide thin film was patterned into an island shape by photolithography to form the channel layer 11. First, a film of a photoresist was formed on the oxide thin film. AZ1500 (manufactured by AZ Electronic Materials SA) was used as the photoresist. The film was exposed to light through a photomask in which a pattern was formed. After the exposure, development was performed with tetramethylammonium hydroxide (TMAH). After the development, the oxide thin film was etched with oxalic acid (ITO-06N manufactured by Kanto Chemical Co., Inc.). After the etching, the photoresist was peeled off. Thus, a substrate with a patterned oxide thin film (channel layer 11) was obtained.

### (4) Annealing

Next, the substrate having the channel layer 11 formed thereabove was placed in a furnace. The temperature inside the furnace was increased to 350° C. at 10° C./min in the atmosphere, and was then held for 1 hour. After the temperature inside the furnace was held at 350° C. for 1 hour, the furnace was allowed to cool naturally. After the temperature inside the furnace returned to room temperature, the substrate was removed from the furnace.

### (5) Si Supply Treatment

Next, the channel layer 11 was subjected to Si supply treatment by the following method.

First, a SiOₓ layer (Si supply source) having a thickness of 10 nm was formed by sputtering through use of a sputtering target of SiO₂.

The SiOₓ layer (Si supply source) constitutes a gate insulating film 24 together with a SiOₓ layer having a thickness of 100 nm, that is formed in the below-mentioned “(7) Formation of Gate Insulating Film 24”.
Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate (S) and target (T): 70 mm

The thickness of the SiOₓ layer formed by the sputtering is shown in the row of “Supplied Amount” in Table 1-1.

### (6) Annealing for Si Diffusion

Next, the substrate on which the SiOₓ layer was formed was placed in a furnace. The temperature inside the furnace was increased to 400° C. at 10° C./min in the atmosphere, and was then held for 1 hour. After the temperature inside the furnace was held at 400° C. for 1 hour, the furnace was allowed to cool naturally. After the temperature inside the furnace returned to room temperature, the substrate 21 was removed from the furnace.

### (7) Formation of Gate Insulating Film 24

Next, a SiOₓ layer having a thickness of 100 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 300 W
Distance between substrate (S) and target (T): 70 mm

As a result, the SiOₓ layer (thickness: 100 nm) formed in this step is formed, and is integrated with the SiOₓ layer (thickness: 10 nm) formed in the above-mentioned “(5) Si Supply Treatment” to become the gate insulating film 24. The total thickness of the gate insulating film 24 was 110 nm.

### (8) Annealing of Gate Insulating Film 24

Next, the substrate having the gate insulating film 24 formed thereabove was placed in a furnace. The temperature inside the furnace was increased to 400° C. at 10° C./min in the atmosphere, and was then held for 1 hour. After the temperature inside the furnace was held at 400° C. for 1 hour, the furnace was allowed to cool naturally. After the temperature inside the furnace returned to room temperature, the substrate 21 was removed from the furnace.

### (9) Formation of Gate Electrode 25

Next, a Mo film having a thickness of 150 nm was formed through use of a sputtering target of Mo. Sputtering conditions are as described below.
Substrate temperature: 25° C.
Ultimate pressure: 8.5×10⁻⁵ Pa
Atmospheric gas: Ar
Sputtering pressure (total pressure): 0.4 Pa
Input voltage: DC 100 W
Distance between substrate (S) and target (T): 70 mm

### (10) Patterning of Gate Electrode 25 and Gate Insulating Film 24

Next, the Mo film and the gate insulating film 24 were patterned into an island shape by photolithography. First, a film of a photoresist was formed on the Mo film. AZ1500 (manufactured by AZ Electronic Materials SA) was used as the photoresist. The film was exposed to light through a photomask in which a pattern was formed. After the exposure, development was performed with tetramethylammonium hydroxide (TMAH). After the development, a gate electrode 25 was formed by etching the Mo film with a mixed acid of phosphoric acid, nitric acid, and acetic acid (phosphoric-acetic-nitric acid (PAN)).

Then, the gate insulating film 24 was etched with buffered hydrofluoric acid (BHF) and patterned into an island shape.

Next, after the photoresist was peeled off, a region in which the channel layer 11 was exposed was etched by a thickness of 10 nm through use of oxalic acid (ITO-06N manufactured by Kanto Chemical Co., Inc.), followed by cleaning.

The dimensions of a portion in which the resultant gate electrode layer 25 and gate insulating film 24 overlapped with the channel layer 11 were a width of 10 μm by a length of 20 μm.

### (11) Low-Resistance Treatment

Low-resistance regions A (11A-1 and 11A-2) were formed in the channel layer 11 by self-alignment using the gate electrode 25. An ITO layer 23 having a thickness of 2 nm was formed through use of a sputtering target of ITO. Sputtering conditions are as described below.
Substrate temperature: 25° C.
Ultimate pressure: 8.5×10⁻⁵ Pa
Atmospheric gas: mixed gas of Ar+O₂ (O₂ flow rate: 2%)
Sputtering pressure (total pressure): 0.4 Pa
Input voltage: DC 100 W
Distance between substrate (S) and target (T): 70 mm

Next, the substrate after the low-resistance treatment was placed in a furnace. The temperature inside the furnace was increased to 350° C. at 10° C./min in the atmosphere, and was then held for 1 hour. Thus, the substrate was annealed. After the temperature inside the furnace was held at 350° C. for 1 hour, the furnace was allowed to cool naturally. After the temperature inside the furnace returned to room temperature, the substrate was removed from the furnace.

### (12) Formation of Interlayer Insulating Film 26

Next, a SiOₓ layer (interlayer insulating film 26) having a thickness of 150 nm was formed by sputtering through use of a sputtering target of SiO₂. Sputtering conditions are as described below.
Substrate temperature: 25° C.
Ultimate pressure: 8.5×10⁻⁵ Pa
Atmospheric gas: mixed gas of Ar+O₂ (O₂ flow rate: 30%)
Sputtering pressure (total pressure): 0.4 Pa
Input voltage: RF 100 W
Distance between substrate (S) and target (T): 70 mm

### (13) Formation of Contact Hole in Interlayer Insulating Film 26

The substrate having the interlayer insulating film 26 formed thereabove was coated with a photoresist AZ1500 (manufactured by AZ Electronic Materials SA) and exposed to light through a photomask. After that, development was performed with tetramethylammonium hydroxide (TMAH). After the development, a contact hole having a width of 12 μm and a length of 18 μm was formed with buffered hydrofluoric acid (BHF).

### (14) Formation of Source Electrode 27 and Drain Electrode 28

The source electrode 27 and the drain electrode 28 were patterned by a lift-off process through use of an image reversal resist AZ5214 and a photomask. The image reversal resist AZ5214 was exposed to light through a photomask. The resist was subjected to a reversal baking step, and was then subjected to full exposure and development with TMAH. A Mo layer having a thickness of 150 nm was formed on the substrate with the patterned resist under the following sputtering conditions.
Substrate temperature: 25° C.
Ultimate Pressure: 8.5×10⁻⁵ Pa
Atmospheric gas: Ar
Sputtering pressure (total pressure): 0.4 Pa
Input voltage: DC 100 W
Distance between substrate (S) and target (T): 70 mm

After that, the substrate having the Mo layer formed thereabove was lifted off in acetone. Thus, the source electrode 27 and the drain electrode 28 were patterned.

### (15) Final Annealing

Finally, the resultant was annealed at 300° C. for 1 hour in a N₂ atmosphere to provide a self-aligned top-gate structure small TFT.

The production conditions for the TFT are summarized in Tables 1-1 to 1-5 and Table 2.

### Examples 2 to 4

Each TFT was produced in the same manner as in Example 1 except that the thickness of the channel layer formed in “(2) Formation of Oxide Thin Film” was changed as shown in Table 1-1.

### Examples 5 to 6

Each TFT was produced in the same manner as in Example 1 except that the thickness of the SiOₓ layer (Si supply source) formed in “(5) Si supply Treatment” was changed as shown in Table 1-1.

### Example 7

A TFT was produced in the same manner as in Example 6 except that “(7) Deposition of Gate Insulating Film 24” and “(8) Annealing of Gate Insulating Film 24” were not performed.

In Example 7, the 100 nm thick SiO₂ layer formed in “(5) Si Supply Treatment” constitutes the gate insulating film 24.

### Example 8

A TFT was produced in the same manner as in Example 1 except that the conditions (temperature increase pattern, highest temperature, and retention time) of “(6) Annealing for Si Diffusion” were changed as shown in Table 1-2.

### Example 9

A TFT was produced in the same manner as in Example 1 except that “(7) Formation of Gate Insulating Film 24” was performed by chemical vapor deposition (CVD) instead of sputtering.

The chemical vapor deposition (CVD) process was performed as follows.

First, the substrate after “(6) Annealing for Si Diffusion” was set in a plasma CVD apparatus, the substrate was held at 350° C., and SiH₄ was introduced at a rate of 2 sccm, N₂O at 100 sccm, and N₂ at 120 sccm at a pressure of 110 Pa, to form a 100 nm thick SiOₓ layer.

### Example 10

A TFT was produced in the same matter as in Example 9 except that “(8) Annealing of Gate Insulating Film 24” was not performed.

### Example 11

A TFT was produced in the same manner as in Example 1 except that “(5) Si supply Treatment” in Example 1 was performed by chemical vapor deposition (CVD) treatment instead of sputtering.

The chemical vapor deposition (CVD) treatment was performed by the following method.

First, the substrate after “(4) Annealing” was performed was set in a plasma CVD device. The substrate was held at 350° C., and SiH₄ at a flow rate of 2 sccm, N₂O at a flow rate of 100 sccm, and N₂ at a flow rate of 120 sccm were introduced under a pressure of 110 Pa to form a SiOₓ layer having a thickness of 10 nm.

### Example 12

In “(5) Si Supply Treatment”, the gas introduced into the plasma CVD device was changed from a mixed gas of SiH₄, N₂O, and N₂ to a mixed gas of SiH₄ and NH₃, and a 10 nm thick SiNₓ layer (Si supply source) was formed in the same manner as in Example 11. The other steps were performed in the same manner as in Example 1. Thus, a TFT was produced.

### Example 13

A TFT was produced in the same manner as in Example 11 except that the thickness of the SiOₓ layer formed by CVD in “(5) Si Supply Treatment” was changed as shown in Table 1-2, and “(6) Annealing for Si Diffusion”, “(7) Formation of Gate Insulating Film 24”, and “(8) Annealing of Gate Insulating Film 24” were not performed.

### Example 14

A TFT was produced in the same manner as in Example 13 except that in “(5) Si Supply Treatment” in Example 13, the holding temperature of the substrate set in the plasma CVD apparatus was changed as shown in Table 1-2.

### Example 15

A Si layer having a thickness of 10 nm was formed in the same matter as in Example 1 except that in “(5) Si Supplying Treatment” of Example 1, a Si sputtering target was used instead of the SiO₂ sputtering target, and Ar gas was used instead of the mixed gas of Ar and O₂ as the sputtering atmosphere gas.

The other steps were performed in the same manner as in Example 1. Thus, a TFT was produced.

### Example 16

A TFT was produced in the same manner as in Example 1 except that in “(5) Si supply Treatment” in Example 1, ion implantation of Si cations was performed into channel layer 11 instead of film formation by sputtering.

The ion implantation was performed using an ion implanter under conditions of an amount of implantation energy of 50 keV.

The dose amount of Si cations by ion implantation is shown in the “Supply Amount” column of Table 1-3.

### Example 17

A TFT was produced in the same manner as in Example 16 except that the thickness of the channel layer formed in “(2) Formation of Oxide Thin Film” in Example 16 was changed as shown in Table 1-3, and the dose amount of Si cations by ion implantation in “(5) Si Supply Treatment” was changed as shown in Table 1-3.

### Example 18

A TFT was produced in the same manner as in Example 16 except that in the “(5) Si Supplying Treatment” in Example 16, the dose amount of Si cations by ion implantation was changed as shown in Table 1-3, and “(6) Si diffusion annealing” was not performed.

### Example 19

In “(7) Formation of Gate Insulating Film 24” in Example 18, an Al₂O₃ sputtering target was used instead of a SiO₂ sputtering target, and an Al₂O₃ layer having a thickness of 100 nm was formed in the same manner as in Example 18. The other steps were performed in the same manner as in Example 18. Thus, a TFT was produced.

### Example 20

A TFT was produced in the same manner as in Example 1 except that in “(2) Formation of Oxide Thin Film” in Example 1, the oxygen partial pressure of the film formation atmosphere gas during the formation of the channel layer was changed as shown in Table 1-3.

### Examples 21 to 22

Each TFT was produced in the same manner as in Example 1 except that in “(2) Formation of Oxide Thin Film” in Example 1, the composition ratio of the sputtering target used for forming the channel layer was changed as shown in Table 1-4.

### Example 23

A TFT was produced in the same manner as in Example 22 except that the oxygen partial pressure and water pressure of the film formation atmosphere gas during the deposition of the channel layer were changed as shown in Table 1-4.

### Example 24

A TFT was produced in the same manner as in Example 1 except that in “(2) Formation of Oxide Thin Film” in Example 1, the composition ratio of the sputtering target used for forming the channel layer was changed as shown in Table 1-4.

### Example 25

A TFT was produced in the same manner as in Example 24 except that the oxygen partial pressure and water pressure of the film formation atmosphere gas during the formation of the channel layer were changed as shown in Table 1-4.

### Example 26

A TFT was produced in the same manner as in Example 1 except that in “(2) Formation of Oxide Thin Film” in Example 1, the composition ratio of the sputtering target used for forming the channel layer was changed as shown in Table 1-4.

### Example 27

A TFT was produced in the same manner as in Example 1 except that the oxygen partial pressure and water pressure of the film formation atmosphere gas during the formation of the channel layer were changed as shown in Table 1-4.

### Comparative Example 1

A TFT was produced in the same manner as in Example 1 except that the thickness of the channel layer formed in “(2) Formation of Oxide Thin Film” in Example 1 was changed as shown in Table 1-5.

### Comparative Example 2

A TFT was produced in the same manner as in Example 1 except that the highest temperature in “(6) Annealing for Si Diffusion” in Example 1 was changed as shown in Table 1-5, and the highest temperature in “(8) Annealing of Gate Insulating Film 24” in Example 1 was changed as shown in Table 1-5.

### Comparative Example 3

A TFT was produced in the same manner as in Example 11 except that in “(2) Formation of Oxide Thin Film”, the thickness of the channel layer formed was changed as shown in Table 1-5, and in “(5) Si Supply Treatment” in Example 11, the holding temperature of the substrate set in the plasma CVD apparatus was changed as shown in Table 1-5.

### Comparative Example 4

A TFT was produced in the same manner as in Example 13 except that in “(5) Si Supply Treatment” in Example 13, the holding temperature of the substrate set in the plasma CVD apparatus was changed as shown in Table 1-5.

### Comparative Example 5

A TFT was produced in the same manner as in Example 1 except that in “(2) Formation of Oxide Thin Film” in Example 1, the composition ratio of the sputtering target used for forming the channel layer was changed as shown in Table 1-5.

### Comparative Example 6

A TFT was produced in the same manner as in Example 1 except that in the “(5) Si Supply Treatment” in Example 1, an Al₂O₃ sputtering target was used instead of a SiO₂ sputtering target.

### Comparative Example 7

A TFT was produced in the same manner as in Example 2 except that the highest temperature in “(6) Annealing for Si Diffusion” in Example 2 was changed as shown in Table 1-5.

The TFTs obtained in Examples and Comparative Examples were evaluated as follows. The results are shown in Tables 1-1 to 1-5. In Tables, “E+XX” means “×10^{XX}.”

### (A) Evaluation Regarding Laminate Structure of TFT

### (1) Average Si Concentration in Channel Layer (Crystalline Oxide Semiconductor Film)

The average Si concentration (average concentration of Si (silicon) relative to all detectable atoms contained in the channel layer) in the channel layer (crystalline oxide semiconductor film) represented by the following formula (1) was measured by transmission electron microscopy-energy dispersive X-ray spectroscopy (TEM-EDX).

$$( Number of silicon ( Si ) atoms contained in crystalline oxide semiconductor film ) / ( Total number of atoms contained in crystalline oxide semiconductor film ) \times 100 \qquad ( 1 )$$

The measurement of the average Si concentration in the channel layer (crystalline oxide semiconductor film) by the TEM-EDX was performed as described below.

First, the TFT obtained in each of Examples and Comparative Examples was processed with a focused ion beam (FIB) at an acceleration voltage of from 20 kV to 30 kV with a composite beam processing and observation device (“JIB-4700F” manufactured by JEOL Ltd.). After that, a thin film sample for cross-sectional TEM observation was picked up by a micro-sampling method at an acceleration voltage of 40 kV with a focused ion beam (FIB) processing and observation device (“FB-2100” manufactured by Hitachi High-Technologies Corporation).

Thin film samples for cross-sectional TEM observation were prepared as thin films that included the entire area in the thickness direction (laminating direction of the TFT) of the channel layer, and were prepared so that they had the same film thickness (film thickness: 60 to 80 nm) in all Examples and Comparative Examples.

Note that the thin film sample for cross-sectional TEM observation in Example 7 was picked up from the interface side of the channel layer (thickness 100 nm) with the gate insulating film, so as to include as much of the channel layer as possible.

Next, the thin film sample for cross-sectional TEM observation was subjected to cross-sectional TEM observation, and EDX line analysis was performed in the film thickness direction from the buffer layer 22 side to the gate insulating film 24 side for a field of view including the channel layer (crystalline oxide semiconductor film) at a central location of the channel layer (crystalline oxide semiconductor film).

The EDX analysis was performed with an energy dispersive X-ray analyzer (“JED-2300T” manufactured by JEOL Ltd.) under the following conditions.
Acceleration voltage: 200 kV
Measurement mode: STEM mode
Spot diameter: 0.16 nm
Measurement interval: 1 nm

The EDX analysis was performed by selecting, as the elements to be detected (detectable elements), in addition to Si, all of the constituent elements of the channel layer (crystalline oxide semiconductor film), the gate insulating film, and the buffer layer that could be detected by the device, and performing a line analysis in the film thickness direction of the channel layer (crystalline oxide semiconductor film).

The average Si concentration represented by the above formula (1) was calculated by automatically calculating the EDX spectrum intensity obtained by the EDX line analysis using initial setting values by a dedicated software of an energy dispersive X-ray analyzer (manufactured by JEOL Ltd., “JED-2300T”).

The average Si concentration was calculated by arithmetically averaging the Si concentrations calculated based on the amounts of Si obtained at each measurement point in the EDX line analysis described above.

In addition, regarding the channel layer (crystalline oxide semiconductor film) region in the TFT, the above-mentioned EDX line analysis was performed on concentrations of all cations contained in the channel layer, and a region showing a value of the largest In concentration in the cation concentrations of the respective cations (concentrations of the respective cations with respect to all detectable atoms contained in the channel layer) was defined as the channel layer (crystalline oxide semiconductor film) region.

### (B) Evaluation Regarding Performance of TFT

The resultant TFT was measured with a semiconductor parameter analyzer (“B1500” manufactured by Agilent) at room temperature under a light-shielding environment (inside a shield box). A drain voltage (Vd) of 20 V was applied. A current value Id was measured at a gate voltage (Vg) of from −5 V to 20 V in increments of 0.1 V for the application of the Vd. Thus, Id-Vg characteristics were obtained.

Various parameters calculated from the Id-Vg characteristics are shown in Tables 1-1 to 1-5. A calculation method for each parameter is as described below.

### (a) Maximum Value of Saturation Mobility

For the maximum value of a saturation mobility at the time of the application of a Vd of 20 V, a graph of Id-Vg characteristics was created, a transconductance (Gm) at each Vg was calculated, and the saturation mobility (μₛₐₜ) was derived with the formula of a saturation region. Specifically, the Gm was calculated by the following mathematical formula (c1).

$$Gm = \partial ( \sqrt{Id} ) / \partial ( Vg ) \qquad ( c1 )$$

Further, the μₛₐₜ was calculated by the following formula (c) of the saturation region.

$${μ}_{sat} = ( 2 \cdot Gm \cdot L ) / ( W \cdot Ci ) \qquad ( c )$$

In the formula (c), L represents a channel length (L length), and W represents a channel width (W length).

Further, the maximum value of the μₛₐₜ at a Vg of from 0 V to 20 V was calculated from each Vg-μₛₐₜ graph.

### (b) Reliability of Self-Aligned Small TFT (High Temperature and High Humidity Resistance Test)

The high temperature and high humidity resistance of the TFT was evaluated.

In the high temperature and high humidity resistance test, the TFT was kept in a high temperature and high humidity environment of a temperature of 85° C. and a humidity of 85% for 72 hours, and the threshold voltage (Vth) before and after being kept in the high temperature and high humidity environment was compared, and the difference was taken as ΔVth.

The threshold voltage (Vth) was calculated by taking the value of Vg at a current value Id=10⁻⁸ [A] in a graph of Id-Vg characteristics as the threshold voltage (Vth).

TABLE 1-1

| | | | Example 1 | Example 2 | Example 3 | Example 4 |
|---|---|---|---|---|---|---|
| Sputtering | Loaded composition ratio | In₂O₃ | 95.0 | 95.0 | 95.0 | 95.0 |
| target | [mass %] | Ga₂O₃ | 5.0 | 5.0 | 5.0 | 5.0 |
| | | Other additive elements | 0.0 | 0.0 | 0.0 | 0.0 |
| | Metal composition ratio | In | 92.8 | 92.8 | 92.8 | 92.8 |
| | [at %] | Ga | 7.2 | 7.2 | 7.2 | 7.2 |
| | | Other additive elements | 0.0 | 0.0 | 0.0 | 0.0 |
| TFT | Formation of channel layer | Pressure at time of film formation [Pa] | 0.5 | 0.5 | 0.5 | 0.5 |
| production | | Oxygen partial pressure at | 0.00 | 0.00 | 0.00 | 0.00 |
| conditions | | time of film formation [Pa] | | | | |
| | | Water partial pressure at time | 0.01 | 0.01 | 0.01 | 0.01 |
| | | of film formation [Pa] | | | | |
| | | Magnetic flux density [G] | 600 | 600 | 600 | 600 |
| | | Thickness [nm] | 10 | 30 | 40 | 5 |
| | Channel layer patterning | Semiconductor etching | Oxalic acid | Oxalic acid | Oxalic acid | Oxalic acid |
| | Annealing | Temperature increase | 10 | 10 | 10 | 10 |
| | | pattern [° C./min] | | | | |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Si Supply method | Si Supply Source | SiO₂ | SiO₂ | SiO₂ | SiO₂ |
| | | Supplied Amount (Film Thickness | 10 | 10 | 10 | 10 |
| | | [nm] or Dose Amount) | | | | |
| | | Si Supply Method | Sputtering | Sputtering | Sputtering | Sputtering |
| | Annealing for | Temperature increase | 10 | 10 | 10 | 10 |
| | Si Diffusion | pattern [° C./min] | | | | |
| | | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | | Film Formation Method | Sputtering | Sputtering | Sputtering | Sputtering |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| Evaluation | Refer to Table 2 for continuation of TFT production conditions | | | | | |
| results | Average Si Concentration in Crystalline Oxide Semiconductor film [at %] | | 5.3 | 2.1 | 1.5 | 8.5 |
| | TFT characteristics | Maximum value of saturation mobility | 40.0 | 50.0 | 60.0 | 35.0 |
| | | [cm²/Vs] | | | | |
| | | High Temperature and High | 0.3 | 0.5 | 0.9 | 0.2 |
| | | Humidity resistance ΔVth[V] | | | | |

| | | | Example 5 | Example 6 | Example 7 |
|---|---|---|---|---|---|
| Sputtering | Loaded composition ratio | In₂O₃ | 95.0 | 95.0 | 95.0 |
| target | [mass %] | Ga₂O₃ | 5.0 | 5.0 | 5.0 |
| | | Other additive elements | 0.0 | 0.0 | 0.0 |
| | Metal composition ratio | In | 92.8 | 92.8 | 92.8 |
| | [at %] | Ga | 7.2 | 7.2 | 7.2 |
| | | Other additive elements | 0.0 | 0.0 | 0.0 |
| TFT | Formation of channel layer | Pressure at time of film formation [Pa] | 0.5 | 0.5 | 0.5 |
| production | | Oxygen partial pressure at | 0.00 | 0.00 | 0.00 |
| conditions | | time of film formation [Pa] | | | |
| | | Water partial pressure at time | 0.01 | 0.01 | 0.01 |
| | | of film formation [Pa] | | | |
| | | Magnetic flux density [G] | 600 | 600 | 600 |
| | | Thickness [nm] | 10 | 10 | 10 |
| | Channel layer patterning | Semiconductor etching | Oxalic acid | Oxalic acid | Oxalic acid |
| | Annealing | Temperature increase | 10 | 10 | 10 |
| | | pattern [° C./min] | | | |
| | | Highest temperature [° C.] | 350 | 350 | 350 |
| | | Retention time [hour] | 1 | 1 | 1 |
| | | Atmosphere | Atmospheric | Atmospheric | Atmospheric |
| | Si Supply method | Si Supply Source | SiO₂ | SiO₂ | SiO₂ |
| | | Supplied Amount (Film Thickness | 5 | 100 | 100 |
| | | [nm] or Dose Amount) | | | |
| | | Si Supply Method | Sputtering | Sputtering | Sputtering |
| | Annealing for | Temperature increase | 10 | 10 | 10 |
| | Si Diffusion | pattern [° C./min] | | | |
| | | Highest temperature [° C.] | 400 | 400 | 400 |
| | | Retention time [hour] | 1 | 1 | 1 |
| | | Atmosphere | Atmospheric | Atmospheric | Atmospheric |
| | Formation of gate | Gate insulating film | SiO₂ | SiO₂ | — |
| | insulating film | Thickness [nm] | 100 | 100 | — |
| | | Film Formation Method | Sputtering | Sputtering | — |
| | Annealing | Highest temperature [° C.] | 400 | 400 | — |
| | | Retention time [hour] | 1 | 1 | — |
| | | Atmosphere | Atmospheric | Atmospheric | — |

| | | | | |
|---|---|---|---|---|
| Evaluation | Refer to Table 2 for continuation of TFT production conditions | | | |
| results | Average Si Concentration in Crystalline Oxide Semiconductor film [at %] | 3.5 | 1.8 | 1.6 |

| | | | | |
|---|---|---|---|---|
| TFT characteristics | Maximum value of saturation mobility | 45.0 | 60.0 | 70.0 |
| | [cm²/Vs] | | | |
| | High Temperature and High | 0.4 | 0.6 | 0.8 |
| | Humidity resistance ΔVth[V] | | | |

TABLE 1-2

| | | | Example 8 | Example 9 | Example 10 | Example 11 |
|---|---|---|---|---|---|---|
| Sputtering | Loaded composition ratio | In₂O₃ | 95.0 | 95.0 | 95.0 | 95.0 |
| target | [mass %] | Ga₂O₃ | 5.0 | 5.0 | 5.0 | 5.0 |
| | | Other additive elements | 0.0 | 0.0 | 0.0 | 0.0 |
| | Metal composition ratio | In | 92.8 | 92.8 | 92.8 | 92.8 |
| | [at %] | Ga | 7.2 | 7.2 | 7.2 | 7.2 |
| | | Other additive elements | 0.0 | 0.0 | 0.0 | 0.0 |
| TFT | Formation of channel layer | Pressure at time of film formation [Pa] | 0.5 | 0.5 | 0.5 | 0.5 |
| production | | Oxygen partial pressure at | 0.00 | 0.00 | 0.00 | 0.00 |
| conditions | | time of film formation [Pa] | | | | |
| | | Water partial pressure at time | 0.01 | 0.01 | 0.01 | 0.01 |
| | | of film formation [Pa] | | | | |
| | | Magnetic flux density [G] | 600 | 600 | 600 | 600 |
| | | Thickness [nm] | 10 | 10 | 10 | 10 |
| | Channel layer patterning | Semiconductor etching | Oxalic acid | Oxalic acid | Oxalic acid | Oxalic acid |
| | Annealing | Temperature increase pattern | 10 | 10 | 10 | 10 |
| | | [° C./min] | | | | |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Si Supply method | Si Supply Source | SiO₂ | SiO₂ | SiO₂ | SiO₂ |
| | | Supplied Amount (Film Thickness | 10 | 10 | 10 | 10 |
| | | [nm] or Dose Amount) | | | | |
| | | Si Supply Method | Sputtering | Sputtering | Sputtering | CVD(350° C.) |
| | Annealing for | Temperature increase pattern | 100 | 10 | 10 | 10 |
| | Si Diffusion | [° C./min] | | | | |
| | | Highest temperature [° C.] | 250 | 400 | 400 | 400 |
| | | Retention time [hour] | 0.5 | 1 | 1 | 1 |
| | | Atmosphere | Atmospheric | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | | Film Formation Method | Sputtering | CVD(350° C.) | CVD(350° C.) | Sputtering |
| | Annealing | Highest temperature [° C.] | 400 | 400 | — | 400 |
| | | Retention time [hour] | 1 | 1 | — | 1 |
| | | Atmosphere | Atmospheric | Atmospheric | — | Atmospheric |
| Evaluation | Refer to Table 2 for continuation of TFT production conditions | | | | | |
| results | Average Si Concentration in Crystalline Oxide Semiconductor film [at %] | | 1.5 | 1.8 | 1.7 | 4.5 |
| | TFT characteristics | Maximum value of saturation mobility | 75.0 | 60.0 | 65.0 | 45.0 |
| | | [cm²/Vs] | | | | |
| | | High Temperature and High Humidity | 0.9 | 0.6 | 0.7 | 0.4 |
| | | resistance ΔVth[V] | | | | |

| | | | Example 12 | Example 13 | Example 14 |
|---|---|---|---|---|---|
| Sputtering | Loaded composition ratio | In₂O₃ | 95.0 | 95.0 | 95.0 |
| target | [mass %] | Ga₂O₃ | 5.0 | 5.0 | 5.0 |
| | | Other additive elements | 0.0 | 0.0 | 0.0 |
| | Metal composition ratio | In | 92.8 | 92.8 | 92.8 |
| | [at %] | Ga | 7.2 | 7.2 | 7.2 |
| | | Other additive elements | 0.0 | 0.0 | 0.0 |
| TFT | Formation of channel layer | Pressure at time of film formation [Pa] | 0.5 | 0.5 | 0.5 |
| production | | Oxygen partial pressure at | 0.00 | 0.00 | 0.00 |
| conditions | | time of film formation [Pa] | | | |
| | | Water partial pressure at time | 0.01 | 0.01 | 0.01 |
| | | of film formation [Pa] | | | |
| | | Magnetic flux density [G] | 600 | 600 | 600 |
| | | Thickness [nm] | 10 | 10 | 10 |
| | Channel layer patterning | Semiconductor etching | Oxalic acid | Oxalic acid | Oxalic acid |
| | Annealing | Temperature increase pattern | 10 | 10 | 10 |
| | | [° C./min] | | | |
| | | Highest temperature [° C.] | 350 | 350 | 350 |
| | | Retention time [hour] | 1 | 1 | 1 |
| | | Atmosphere | Atmospheric | Atmospheric | Atmospheric |
| | Si Supply method | Si Supply Source | SiNₓ | SiO₂ | SiO₂ |
| | | Supplied Amount (Film Thickness | 10 | 100 | 100 |
| | | [nm] or Dose Amount) | | | |
| | | Si Supply Method | CVD(350° C.) | CVD(350° C.) | CVD(250° C.) |
| | Annealing for | Temperature increase pattern | 10 | — | — |
| | Si Diffusion | [° C./min] | | | |
| | | Highest temperature [° C.] | 400 | — | — |
| | | Retention time [hour] | 1 | — | — |
| | | Atmosphere | Atmospheric | — | — |
| | Formation of gate | Gate insulating film | SiO₂ | — | — |
| | insulating film | Thickness [nm] | 100 | — | — |
| | | Film Formation Method | Sputtering | — | — |
| | Annealing | Highest temperature [° C.] | 400 | — | — |
| | | Retention time [hour] | 1 | — | — |
| | | Atmosphere | Atmospheric | — | — |

| | | | | |
|---|---|---|---|---|
| Evaluation | Refer to Table 2 for continuation of TFT production conditions | | | |
| results | Average Si Concentration in Crystalline Oxide Semiconductor film [at %] | 6.0 | 2.3 | 1.5 |

| | | | | |
|---|---|---|---|---|
| TFT characteristics | Maximum value of saturation mobility | 38.0 | 45.0 | 60.0 |
| | [cm²/Vs] | | | |
| | High Temperature and High Humidity | 0.6 | 0.6 | 0.9 |
| | resistance ΔVth[V] | | | |

TABLE 1-3

| | | | Example 15 | Example 16 | Example 17 | Example 18 |
|---|---|---|---|---|---|---|
| Sputtering | Loaded composition ratio | In₂O₃ | 95.0 | 95.0 | 95.0 | 95.0 |
| target | [mass %] | Ga₂O₃ | 5.0 | 5.0 | 5.0 | 5.0 |
| | | Other additive elements | 0.0 | 0.0 | 0.0 | 0.0 |
| | Metal composition ratio | In | 92.8 | 92.8 | 92.8 | 92.8 |
| | [at %] | Ga | 7.2 | 7.2 | 7.2 | 7.2 |
| | | Other additive elements | 0.0 | 0.0 | 0.0 | 0.0 |
| TFT | Formation of | Pressure at time of | 0.5 | 0.5 | 0.5 | 0.5 |
| production | channel layer | film formation [Pa] | | | | |
| conditions | | Oxygen partial pressure at time | 0.00 | 0.00 | 0.00 | 0.00 |
| | | of film formation [Pa] | | | | |
| | | Water partial pressure at time | 0.01 | 0.01 | 0.01 | 0.01 |
| | | of film formation [Pa] | | | | |
| | | Magnetic flux density [G] | 600 | 600 | 600 | 600 |
| | | Thickness [nm] | 10 | 10 | 100 | 10 |
| | Channel layer patterning | Semiconductor etching | Oxalic acid | Oxalic acid | Oxalic acid | Oxalic acid |
| | Annealing | Temperature increase pattern | 10 | 10 | 10 | 10 |
| | | [° C./min] | | | | |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Si Supply method | Si Supply Source | Si | Si | Si | Si |
| | | Supplied Amount (Film Thickness | 10 | 1 × 10¹⁶ | 5 × 10¹⁶ | 5 × 10¹⁶ |
| | | [nm] or Dose Amount) | | ions/cm² | ions/cm² | ions/cm² |
| | | Si Supply Method | Sputtering | Ion | Ion | Ion |
| | | | | implantation | implantation | implantation |
| | Annealing for | Temperature increase pattern | 10 | 10 | 10 | — |
| | Si Diffusion | [° C./min] | | | | |
| | | Highest temperature [° C.] | 400 | 400 | 400 | — |
| | | Retention time [hour] | 1 | 1 | 1 | — |
| | | Atmosphere | Atmospheric | Atmospheric | Atmospheric | — |
| | Formation of gate | Gate insulating film | SiO₂ | SiO₂ | SiO₂ | SiO₂ |
| | insulating film | Thickness [nm] | 100 | 100 | 100 | 100 |
| | | Film Formation Method | Sputtering | Sputtering | Sputtering | Sputtering |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| Evaluation | Refer to Table 2 for continuation | | | | | |
| results | of TFT production conditions | | | | | |
| | Average Si Concentration in Crystalline | | 9.0 | 5.0 | 2.5 | 5.0 |
| | Oxide Semiconductor film [at %] | | | | | |
| | TFT characteristics | Maximum value of saturation | 30.0 | 50.0 | 30.0 | 45.0 |
| | | mobility [cm²/Vs] | | | | |
| | | High Temperature and High Humidity | 0.1 | 0.2 | 0.4 | 0.2 |
| | | resistance ΔVth[V] | | | | |

| | | | Example 19 | Example 20 |
|---|---|---|---|---|
| Sputtering | Loaded composition ratio | In₂O₃ | 95.0 | 95.0 |
| target | [mass %] | Ga₂O₃ | 5.0 | 5.0 |
| | | Other additive elements | 0.0 | 0.0 |
| | Metal composition ratio | In | 92.8 | 92.8 |
| | [at %] | Ga | 7.2 | 7.2 |
| | | Other additive elements | 0.0 | 0.0 |
| TFT | Formation of | Pressure at time of | 0.5 | 0.5 |
| production | channel layer | film formation [Pa] | | |
| conditions | | Oxygen partial pressure at time | 0.00 | 0.05 |
| | | of film formation [Pa] | | |
| | | Water partial pressure at time | 0.01 | 0.01 |
| | | of film formation [Pa] | | |
| | | Magnetic flux density [G] | 600 | 600 |
| | | Thickness [nm] | 10 | 10 |
| | Channel layer patterning | Semiconductor etching | Oxalic acid | Oxalic acid |
| | Annealing | Temperature increase pattern | 10 | 10 |
| | | [° C./min] | | |
| | | Highest temperature [° C.] | 350 | 350 |
| | | Retention time [hour] | 1 | 1 |
| | | Atmosphere | Atmospheric | Atmospheric |
| | Si Supply method | Si Supply Source | Si | SiO₂ |
| | | Supplied Amount (Film Thickness | 5 × 10¹⁶ | 10 |
| | | [nm] or Dose Amount) | ions/cm² | |
| | | Si Supply Method | Ion | Sputtering |
| | | | implantation | |
| | Annealing for | Temperature increase pattern | — | 10 |
| | Si Diffusion | [° C./min] | | |
| | | Highest temperature [° C.] | — | 400 |
| | | Retention time [hour] | — | 1 |
| | | Atmosphere | — | Atmospheric |
| | Formation of gate | Gate insulating film | Al₂O₃ | SiO₂ |
| | insulating film | Thickness [nm] | 100 | 100 |
| | | Film Formation Method | Sputtering | Sputtering |
| | Annealing | Highest temperature [° C.] | 400 | 400 |
| | | Retention time [hour] | 1 | 1 |
| | | Atmosphere | Atmospheric | Atmospheric |

| | | | |
|---|---|---|---|
| Evaluation | Refer to Table 2 for continuation | | |
| results | of TFT production conditions | | |
| | Average Si Concentration in Crystalline | 5.0 | 4.8 |
| | Oxide Semiconductor film [at %] | | |

| | | | |
|---|---|---|---|
| TFT characteristics | Maximum value of saturation | 65.0 | 37.0 |
| | mobility [cm²/Vs] | | |
| | High Temperature and High Humidity | 0.2 | 0.4 |
| | resistance ΔVth[V] | | |

TABLE 1-4

| | | | Example 21 | Example 22 | Example 23 | Example 24 |
|---|---|---|---|---|---|---|
| Sputtering | Loaded composition ratio | In₂O₃ | 100.0 | 81.6 | 81.6 | 89.4 |
| target | [mass %] | Ga₂O₃ | 0.0 | 18.4 | 18.4 | 10.6 |
| | | Other additive elements | 0.0 | 0.0 | 0.0 | 0.0 |
| | Metal composition ratio | In | 100.0 | 75.0 | 75.0 | 85.0 |
| | [at %] | Ga | 0.0 | 25.0 | 25.0 | 15.0 |
| | | Other additive elements | 0.0 | 0.0 | 0.0 | 0.0 |
| TFT | Formation of | Pressure at time of | 0.5 | 0.5 | 0.5 | 0.5 |
| production | channel layer | film formation [Pa] | | | | |
| conditions | | Oxygen partial pressure at time | 0.00 | 0.00 | 0.05 | 0.00 |
| | | of film formation [Pa] | | | | |
| | | Water partial pressure at time | 0.01 | 0.01 | 0.00 | 0.01 |
| | | of film formation [Pa] | | | | |
| | | Magnetic flux density [G] | 600 | 600 | 600 | 600 |
| | | Thickness [nm] | 10 | 10 | 10 | 10 |
| | Channel layer patterning | Semiconductor etching | Oxalic acid | Oxalic acid | Oxalic acid | Oxalic acid |
| | Annealing | Temperature increase | 10 | 10 | 10 | 10 |
| | | pattern [° C./min] | | | | |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Si Supply method | Si Supply Source | SiO₂ | SiO₂ | SiO₂ | SiO₂ |
| | | Supplied Amount (Film Thickness | 10 | 10 | 10 | 10 |
| | | [nm] or Dose Amount) | | | | |
| | | Si Supply Method | Sputtering | Sputtering | Sputtering | Sputtering |
| | Annealing for | Temperature increase | 10 | 10 | 10 | 10 |
| | Si Diffusion | pattern [° C./min] | | | | |
| | | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| | Formation of gate | Gate insulating film | SiO₂ | SiO₂ | SiO₂ | SiO₂ |
| | insulating film | Thickness [nm] | 100 | 100 | 100 | 100 |
| | | Film Formation Method | Sputtering | Sputtering | Sputtering | Sputtering |
| | Annealing | Highest temperature [° C.] | 400 | 400 | 400 | 400 |
| | | Retention time [hour] | 1 | 1 | 1 | 1 |
| | | Atmosphere | Atmospheric | Atmospheric | Atmospheric | Atmospheric |
| Evaluation | Refer to Table 2 for continuation | | | | | |
| results | of TFT production conditions | | | | | |
| | Average Si Concentration in Crystalline | | 5.0 | 5.2 | 5.3 | 5.2 |
| | Oxide Semiconductor film [at %] | | | | | |
| | TFT characteristics | Maximum value of saturation | 48.0 | 32.0 | 31.0 | 36.0 |
| | | mobility [cm²/Vs] | | | | |
| | | High Temperature and High Humidity | 0.6 | 0.3 | 0.2 | 0.4 |
| | | resistance ΔVth[V] | | | | |

| | | | Example 25 | Example 26 | Example 27 |
|---|---|---|---|---|---|
| Sputtering | Loaded composition ratio | In₂O₃ | 89.4 | 89.0 | 89.0 |
| target | [mass %] | Ga₂O₃ | 10.6 | 9.8 | 9.8 |
| | | Other additive elements | 0.0 | Al₂O₃ 1.2 | Al₂O₃ 1.2 |
| | Metal composition ratio | In | 85.0 | 83.2 | 83.2 |
| | [at %] | Ga | 15.0 | 13.5 | 13.5 |
| | | Other additive elements | 0.0 | Al 3.3 | Al 3.3 |
| TFT | Formation of | Pressure at time of | 0.5 | 0.5 | 0.5 |
| production | channel layer | film formation [Pa] | | | |
| conditions | | Oxygen partial pressure at time | 0.05 | 0.00 | 0.05 |
| | | of film formation [Pa] | | | |
| | | Water partial pressure at time | 0.00 | 0.01 | 0.00 |
| | | of film formation [Pa] | | | |
| | | Magnetic flux density [G] | 600 | 600 | 600 |
| | | Thickness [nm] | 10 | 10 | 10 |
| | Channel layer patterning | Semiconductor etching | Oxalic acid | Oxalic acid | Oxalic acid |
| | Annealing | Temperature increase | 10 | 10 | 10 |
| | | pattern [° C./min] | | | |
| | | Highest temperature [° C.] | 350 | 350 | 350 |
| | | Retention time [hour] | 1 | 1 | 1 |
| | | Atmosphere | Atmospheric | Atmospheric | Atmospheric |
| | Si Supply method | Si Supply Source | SiO₂ | SiO₂ | SiO₂ |
| | | Supplied Amount (Film Thickness | 10 | 10 | 10 |
| | | [nm] or Dose Amount) | | | |
| | | Si Supply Method | Sputtering | Sputtering | Sputtering |
| | Annealing for | Temperature increase | 10 | 10 | 10 |
| | Si Diffusion | pattern [° C./min] | | | |
| | | Highest temperature [° C.] | 400 | 400 | 400 |
| | | Retention time [hour] | 1 | 1 | 1 |
| | | Atmosphere | Atmospheric | Atmospheric | Atmospheric |
| | Formation of gate | Gate insulating film | SiO₂ | SiO₂ | SiO₂ |
| | insulating film | Thickness [nm] | 100 | 100 | 100 |
| | | Film Formation Method | Sputtering | Sputtering | Sputtering |
| | Annealing | Highest temperature [° C.] | 400 | 400 | 400 |
| | | Retention time [hour] | 1 | 1 | 1 |
| | | Atmosphere | Atmospheric | Atmospheric | Atmospheric |

| | | | | |
|---|---|---|---|---|
| Evaluation | Refer to Table 2 for continuation | | | |
| results | of TFT production conditions | | | |
| | Average Si Concentration in Crystalline | 5.4 | 5.5 | 5.5 |
| | Oxide Semiconductor film [at %] | | | |

| | | | | |
|---|---|---|---|---|
| TFT characteristics | Maximum value of saturation | 35.0 | 32.0 | 38.0 |
| | mobility [cm²/Vs] | | | |
| | High Temperature and High Humidity | 0.3 | 0.3 | 0.4 |
| | resistance ΔVth[V] | | | |

TABLE 1-5

| | | | Comparative | Comparative | Comparative | Comparative |
|---|---|---|---|---|---|---|
| | | | Example 1 | Example 2 | Example 3 | Example 4 |
| Sputtering | Loaded composition ratio | In₂O₃ | 95.0 | 95.0 | 95.0 | 95.0 |
| target | [mass %] | Ga₂O₃ | 5.0 | 5.0 | 5.0 | 5.0 |
| | | Other additive elements | 0.0 | 0.0 | 0.0 | 0.0 |
| | Metal composition ratio | In | 92.8 | 92.8 | 92.8 | 92.8 |
| | [at %] | Ga | 7.2 | 7.2 | 7.2 | 7.2 |
| | | Other additive elements | 0.0 | 0.0 | 0.0 | 0.0 |
| TFT | Formation of | Pressure at time of | 0.5 | 0.5 | 0.5 | 0.5 |
| production | channel layer | film formation [Pa] | | | | |
| conditions | | Oxygen partial pressure at time | 0.00 | 0.00 | 0.00 | 0.00 |
| | | of film formation [Pa] | | | | |
| | | Water partial pressure at time | 0.01 | 0.01 | 0.01 | 0.01 |
| | | of film formation [Pa] | | | | |
| | | Magnetic flux density [G] | 600 | 600 | 600 | 600 |
| | | Thickness [nm] | 50 | 10 | 30 | 10 |
| | Channel layer patterning | Semiconductor etching | Oxalic acid | Oxalic acid | Oxalic acid | Oxalic acid |
| | Annealing | Temperature increase | 10 | 10 | 10 | 10 |
| | | pattern [° C./min] | | | | |
| | | Highest temperature [° C.] | 350 | 350 | 350 | 350 |
| | | Retention time [hour] | 1 | 1 | 1 | 1 |
| | | Atmosphere | Atmospheric | Atmospheric | Atmospheric | Atmospheric |
| | Si Supply method | Si Supply Source | SiO₂ | SiO₂ | SiO₂ | SiO₂ |
| | | Supplied Amount (Film Thickness | 10 | 10 | 10 | 100 |
| | | [nm] or Dose Amount) | | | | |
| | | Si Supply Method | Sputtering | Sputtering | CVD(230° C.) | CVD(230° C.) |
| | Annealing for | Temperature increase | 10 | 10 | 10 | — |
| | Si Diffusion | pattern [° C./min] | | | | |
| | | Highest temperature [° C.] | 400 | 230 | 400 | — |
| | | Retention time [hour] | 1 | 1 | 1 | — |
| | | Atmosphere | Atmospheric | Atmospheric | Atmospheric | — |
| | Formation of gate | Gate insulating film | SiO₂ | SiO₂ | SiO₂ | — |
| | insulating film | Thickness [nm] | 100 | 100 | 100 | — |
| | | Film Formation Method | Sputtering | Sputtering | Sputtering | — |
| | Annealing | Highest temperature [° C.] | 400 | 230 | 400 | — |
| | | Retention time [hour] | 1 | 1 | 1 | — |
| | | Atmosphere | Atmospheric | Atmospheric | Atmospheric | — |
| Evaluation | Refer to Table 2 for continuation of | | | | | |
| results | TFT production conditions | | | | | |
| | Average Si Concentration in Crystalline | | 1.0 | 1.2 | 1.4 | 1.1 |
| | Oxide Semiconductor film [at %] | | | | | |
| | TFT characteristics | Maximum value of saturation | 45.0 | 42.0 | 39.0 | 44.0 |
| | | mobility [cm²/Vs] | | | | |
| | | High Temperature and High Humidity | 5.0 | 1.5 | 1.0 | 2.0 |
| | | resistance ΔVth[V] | | | | |

| | | | Comparative | Comparative | Comparative |
|---|---|---|---|---|---|
| | | | Example 5 | Example 6 | Example 7 |
| Sputtering | Loaded composition ratio | In₂O₃ | 69.0 | 95.0 | 95.0 |
| target | [mass %] | Ga₂O₃ | 31.0 | 5.0 | 5.0 |
| | | Other additive elements | 0.0 | 0.0 | 0.0 |
| | Metal composition ratio | In | 60.0 | 92.8 | 92.8 |
| | [at %] | Ga | 40.0 | 7.2 | 7.2 |
| | | Other additive elements | 0.0 | 0.0 | 0.0 |
| TFT | Formation of | Pressure at time of | 0.5 | 0.5 | 0.5 |
| production | channel layer | film formation [Pa] | | | |
| conditions | | Oxygen partial pressure at time | 0.00 | 0.00 | 0.00 |
| | | of film formation [Pa] | | | |
| | | Water partial pressure at time | 0.01 | 0.01 | 0.01 |
| | | of film formation [Pa] | | | |
| | | Magnetic flux density [G] | 600 | 600 | 600 |
| | | Thickness [nm] | 10 | 10 | 30 |
| | Channel layer patterning | Semiconductor etching | Oxalic acid | Oxalic acid | Oxalic acid |
| | Annealing | Temperature increase | 10 | 10 | 10 |
| | | pattern [° C./min] | | | |
| | | Highest temperature [° C.] | 350 | 350 | 350 |
| | | Retention time [hour] | 1 | 1 | 1 |
| | | Atmosphere | Atmospheric | Atmospheric | Atmospheric |
| | Si Supply method | Si Supply Source | SiO₂ | Al₂O₃ | SiO₂ |
| | | Supplied Amount (Film Thickness | 10 | 10 | 10 |
| | | [nm] or Dose Amount) | | | |
| | | Si Supply Method | Sputtering | Sputtering | Sputtering |
| | Annealing for | Temperature increase | 10 | 10 | 10 |
| | Si Diffusion | pattern [° C./min] | | | |
| | | Highest temperature [° C.] | 400 | 400 | 230 |
| | | Retention time [hour] | 1 | 1 | 1 |
| | | Atmosphere | Atmospheric | Atmospheric | Atmospheric |
| | Formation of gate | Gate insulating film | SiO₂ | SiO₂ | SiO₂ |
| | insulating film | Thickness [nm] | 100 | 100 | 100 |
| | | Film Formation Method | Sputtering | Sputtering | Sputtering |
| | Annealing | Highest temperature [° C.] | 400 | 400 | 400 |
| | | Retention time [hour] | 1 | 1 | 1 |
| | | Atmosphere | Atmospheric | Atmospheric | Atmospheric |

| | | | | |
|---|---|---|---|---|
| Evaluation | Refer to Table 2 for continuation of | | | |
| results | TFT production conditions | | | |
| | Average Si Concentration in Crystalline | 1.4 | 0.5 | 1.3 |
| | Oxide Semiconductor film [at %] | | | |

| | | | | |
|---|---|---|---|---|
| TFT characteristics | Maximum value of saturation | 25.0 | 60.0 | 41.0 |
| | mobility [cm²/Vs] | | | |
| | High Temperature and High Humidity | 0.5 | 1.5 | 1.2 |
| | resistance ΔVth[V] | | | |

TABLE 2

| | | | Examples 1 |
|---|---|---|---|
| | | | to 27 and |
| | | | Comparative |
| | | | Examples 1 to 7 |
| TFT | Formation of | Gate electrode | Mo |
| production | gate electrode | Thickness [nm] | 150 |
| conditions | Gate patterning | Gate electrode | PAN |
| (continued) | | etchant | |
| | | Gate insulating | BHF |
| | | film etchant | |
| | | Cleaning etchant | ITO-06N |
| | Formation of | Oxygen | 2.0 |
| | ITO layer | partial | |
| | | pressure | |
| | | at time of film | |
| | | formation [%] | |
| | | Thickness [nm] | 2 |
| | Low- | Highest temperature | 350 |
| | resistance | [° C.] | |
| | annealing | Retention time | 1 |
| | | [hour] | |
| | | Atmosphere | Atmospheric |
| | Formation of | Insulating | SiO₂ |
| | interlayer | film | |
| | insulating film | Thickness [nm] | 150 |
| | Formation of | Etchant | BHF |
| | contact hole in | | |
| | interlayer | | |
| | insulating film | | |
| | Formation | Electrode | Mo |
| | of electrode | | |
| | Final annealing | Highest | 300 |
| | | temperature | |
| | | [° C.] | |
| | | Retention time | 1 |
| | | [hour] | |
| | | Atmosphere | N₂ |

As shown in Tables 1-1 to 1-5, the TFTs of Examples 1 to 6, 8, 11 to 12, 15, and 20 to 27 in which the gate insulating film 24 was formed by sputtering and annealing had an average silicon concentration in the crystalline oxide semiconductor film within the range of 1.5 to 10 at %, exhibited a good mobility of 30 cm²/Vs or more, and had a low ΔVth value in a high-temperature and high-humidity environment, thereby obtaining high reliability.

Furthermore, in the TFTs of Examples 1 to 6, 8, 11 to 12, 15, and 20 to 27, a SiOₓ layer or the like is formed by sputtering or CVD as a Si supply source on the channel layer 11 before the gate insulating film 24 is formed, and ΔVth is therefore suppressed to a lower value.

In particular, in Example 4, the channel layer has a small film thickness of 5 nm, and therefore ΔVth is suppressed to a lower value, resulting in high reliability.

Furthermore, the TFTs of Examples 9 to 10, which were obtained by forming the gate insulating film 24 on the channel layer 11 by CVD, exhibited good mobility and had a low ΔVth in a high temperature and high humidity environment, resulting in high reliability.

Furthermore, in the TFTs of Examples 9 to 10, a SiOₓ layer is formed by sputtering onto the channel layer 11 as a Si supply source before the gate insulating film 24 is formed, so that ΔVth is kept to an even lower value.

In addition, the TFTs of Examples 7, 13 and 14 having a SiOₓ layer (gate insulating film) as a Si supply source obtained by sputtering or CVD on the channel layer 11 exhibited good mobility, and ΔVth was suppressed to a low value under a high temperature and high humidity environment, and high reliability was obtained.

Furthermore, the TFTs of Examples 16 to 19, which were obtained by ion implantation of Si cations (Si supply source) into the channel layer as a Si supply treatment, exhibited good mobility of 30 cm²/Vs or more, and ΔVth in a high temperature and high humidity environment was kept to a low value, resulting in high reliability.

For example, in Example 17, although the channel layer had a relatively large thickness of 100 nm, ΔVth was kept to a low value, resulting in high reliability.

### INDUSTRIAL APPLICABILITY

The laminate structure of the present disclosure can be suitably used as a constituent member of a thin film transistor, for example, a channel layer and a gate insulating film. In addition, the thin film transistor of the present disclosure including the laminate structure of the present disclosure can be used in an electric circuit to be used in an electric device, an electronic device, a vehicle, or a power engine.

Some embodiments and/or Examples of the present disclosure have been described above in detail, but it is easy for a person skilled in the art to add a large number of modifications to these illustrative embodiments and/or Examples without substantially departing from the novel teachings and effects of the present disclosure. Thus, the large number of modifications are encompassed in the scope of the present disclosure.

The literatures described herein and the contents of the applications based on which the priority under the Paris Convention of the present application is claimed are incorporated herein in their entirety.

1. A laminate structure, comprising:
a crystalline oxide semiconductor film containing In as a main component; and
a first insulating film laminated in contact with the crystalline oxide semiconductor film,
wherein the crystalline oxide semiconductor film has an average silicon concentration of 1.5 to 10 at %.

2. The laminate structure according to claim 1, having a second insulating film laminated in contact with the surface of the crystalline oxide semiconductor film opposite to the surface in contact with the first insulating film.

3. The laminate structure according to claim 1, wherein the first insulating film is any one of an oxide film containing silicon (Si) as a main component, a nitride film containing silicon (Si) as a main component, and an oxynitride film containing silicon (Si) as a main component.

4. The laminate structure according to claim 1, wherein the first insulating film is an oxide film containing silicon (Si) as a main component.

5. The laminate structure according to claim 1, wherein the crystalline oxide semiconductor film further contains Ga.

6. The laminate structure according to claim 1, wherein the crystalline oxide semiconductor film further contains one or more kinds of additive elements selected from B, Al, Si, Sc, Zn, Ge, Y, Zr, Sn, Sm, and Yb.

7. The laminate structure according to claim 1, wherein an atomic ratio of In with respect to all metal elements contained in the crystalline oxide semiconductor film ([In]/([In]+[all metal elements except In])×100) is 62 at % or more.

8. The laminate structure according to claim 5, wherein an atomic ratio of Ga with respect to all metal elements contained in the crystalline oxide semiconductor film ([Ga]/([Ga]+[all metal elements except Ga])×100) is 30 at % or less.

9. The laminate structure according to claim 6, wherein an atomic ratio of a total amount of the additive elements with respect to all metal elements contained in the crystalline oxide semiconductor film ([total amount of additive elements]/([total amount of additive elements]+[all metal elements except additive elements])×100) is 10 at % or less.

10. The laminate structure according to claim 1, wherein the crystalline oxide semiconductor film has a carrier concentration at room temperature of 1×10¹⁸ cm⁻³ or less.

11. The laminate structure according to claim 1, wherein the crystalline oxide semiconductor film contains a crystal grain having a bixbyite structure.

12. A thin film transistor, comprising the laminate structure of claim 1,
wherein the thin film transistor includes:
a channel layer;
a source electrode and a drain electrode each connected to the channel layer; and
a gate electrode laminated on the channel layer through intermediation of a gate insulating film,
wherein the channel layer is the crystalline oxide semiconductor film in the laminate structure, and
wherein the gate insulating film is the first insulating film in the laminate structure.

13. The thin film transistor according to claim 12, wherein the thin film transistor is a top-gate type transistor.

14. A semiconductor element, comprising the laminate structure of claim 1.

15. A diode, a thin film transistor, a MOSFET, or a MESFET, comprising the semiconductor element of claim 14.

16. An electronic circuit, comprising the diode, the thin film transistor, the MOSFET, or the MESFET of claim 15.

17. An electric device, an electronic device, a vehicle, or a power engine, comprising the electronic circuit of claim 16.
